(19) United States
(12) Patent Application Publication
(10) Pub. No.: US 2026/0096478 A1
(43) Pub. Date: Apr. 2, 2026

(54) ELECTRONIC DEVICE INCLUDING STACKED SEMICONDUCTOR CHIPS AND METHOD OF MANUFACTURING THE SAME

(71) Applicant: NANYA TECHNOLOGY CORPORATION, NEW TAIPEI CITY (TW)

(72) Inventor: KUO-HUI SU, NEW TAIPEI CITY (TW)

(21) Appl. No.: 18/921,201

(22) Filed: Oct. 21, 2024

Related U.S. Application Data
(62) Division of application No. 18/901,151, filed on Sep. 30, 2024.

(51) Int. Cl. H01L 23/00; H01L 21/56; H01L 21/78; H01L 25/00

(52) U.S. Cl. CPC H10W 90/00; H10P 54/00; H10W 74/014; H10W 72/0198; H10W 72/072; H10W 80/312; H10W 80/327

(57) ABSTRACT

An electronic device and a manufacturing method are provided. The electronic device includes a first semiconductor chip, a second semiconductor chip, a third semiconductor chip, a fourth semiconductor and a fifth semiconductor chip. The second semiconductor chip is stacked on the first semiconductor chip, and is electrically connected to the first semiconductor chip by hybrid bonding. The fourth semiconductor chip is stacked on the third semiconductor chip, and is electrically connected to the third semiconductor chip by hybrid bonding. The third semiconductor chip is stacked on the second semiconductor chip, and is electrically connected to the second semiconductor chip through a plurality of bumps. The fifth semiconductor chip disposed below the first semiconductor chip, and is electrically connected to the first semiconductor chip through a plurality of electrical connectors.

### CROSS-REFERENCE TO RELATED APPLICATION

This application is a divisional application of U.S. Non-Provisional Application No. 18/901,151 filed September 30, 2024, which is incorporated herein by reference in its entirety.

### TECHNICAL FIELD

The present disclosure relates to an electronic device and a method of manufacturing the same, and more particularly, to an electronic device having stacked semiconductor chips, and a method of manufacturing the same.

### DISCUSSION OF THE BACKGROUND

Semiconductor electronic devices are used in various electronic applications, including personal computers, cellular telephones, digital cameras, and other electronic equipment. Size of semiconductor electronic devices are continuously decreasing to meet growing demands for computing power. However, such scaling down presents challenges that are becoming more frequent and impactful. Therefore, there are still challenges to overcome in improving quality, yield, performance and reliability while reducing complexity.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides an electronic device comprising a first semiconductor chip; a second semiconductor chip stacked on the first semiconductor chip, and electrically connected to the first semiconductor chip by hybrid bonding; a third semiconductor chip stacked on the second semiconductor chip, and electrically connected to the second semiconductor chip through a plurality of bumps; a fourth semiconductor chip stacked on the third semiconductor chip, and electrically connected to the third semiconductor chip by hybrid bonding; and a fifth semiconductor chip disposed below the first semiconductor chip, and electrically connected to the first semiconductor chip through a plurality of electrical connectors.

Another aspect of the present disclosure provides an electronic device comprising a first assembly, a second assembly, a base semiconductor chip and a carrier structure. The first assembly comprises a first semiconductor chip and a second semiconductor chip stacked on the first semiconductor chip, and the second semiconductor chip is electrically connected to the first semiconductor chip by hybrid bonding. The second assembly comprises a third semiconductor chip and a fourth semiconductor chip stacked on the third semiconductor chip, and the fourth semiconductor chip is electrically connected to the third semiconductor chip by hybrid bonding. The base semiconductor chip is disposed below the first assembly and electrically connected to the first assembly through a plurality of electrical connectors. The carrier structure is disposed over the second assembly and electrically connected to the second assembly through by a hybrid bonding. The second assembly is electrically connected to the first assembly through a plurality of bumps. The first assembly is electrically connected to the base semiconductor chip through a plurality of electrical connectors.

Another aspect of the present disclosure provides a manufacturing method. The manufacturing method comprises forming a first assembly comprising a first semiconductor chip, a second semiconductor chip and a plurality of electrical connectors, wherein the second semiconductor chip is stacked on the first semiconductor chip, and wherein the electrical connectors are connected to the first semiconductor chip; forming a second assembly comprising a third semiconductor chip, a fourth semiconductor chip and a plurality of bumps, wherein the fourth semiconductor chip is stacked on the third semiconductor chip, and wherein the bumps are connected to the third semiconductor chip; forming a third assembly comprising a fifth semiconductor chip and a plurality of external connectors, wherein the third assembly comprises a fifth lower structure and a fifth upper structure, and wherein the external connectors are connected to the fifth lower structure; forming a carrier structure comprising a carrier substrate, a plurality of through semiconductor vias penetrating the carrier substrate, a plurality of conductive plates on the carrier substrate and the through semiconductor vias, and a bonding layer on the carrier substrate and covering the conductive plates; electrically connecting the second assembly to the first assembly through the plurality of bumps; electrically connecting the first assembly to the third assembly through the plurality of electrical connectors; encapsulating the first assembly, the second assembly and the third assembly with a periphery encapsulant around the first assembly and the second assembly, and on the third assembly; and performing a hybrid bonding to electrically connect the carrier structure to the second assembly and the periphery encapsulant.

The foregoing has outlined rather broadly the features and technical advantages of the present disclosure in order that the detailed description of the disclosure that follows may be better understood. Additional features and advantages of the disclosure are described below, and form the subject of the claims of the disclosure. It should be appreciated by those skilled in the art that the conception and specific embodiments disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a schematic cross-sectional view of an electronic device in accordance with some embodiments of the present disclosure.

FIG. 2 is a schematic cross-sectional view of a semiconductor structure in accordance with some embodiments of the present disclosure.

FIGS. 3 to 11 are various stages of a method of manufacturing an electronic device in accordance with some embodiments of the present disclosure.

FIGS. 12 to 17 are various stages of a method of manufacturing an electronic device in accordance with some embodiments of the present disclosure.

FIGS. 18 to 20 are various stages of a method of manufacturing an electronic device in accordance with some embodiments of the present disclosure.

FIG. 21 is a stage of a method of manufacturing an electronic device in accordance with some embodiments of the present disclosure.

FIG. 22 is an enlarged view of a through semiconductor via in FIG. 21 in accordance with some embodiments of the present disclosure.

FIGS. 23 to 24 are various stages of a method of manufacturing an electronic device in accordance with some embodiments of the present disclosure.

FIGS. 25 to 28 are various stages of a method of manufacturing an electronic device in accordance with some embodiments of the present disclosure.

FIG. 29 is a flow diagram of a method of manufacturing an electronic device in accordance with some embodiments of the present disclosure.

### DETAILED DESCRIPTION

Embodiments, or examples, of the disclosure illustrated in the drawings are now described using a specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It should be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It should be understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

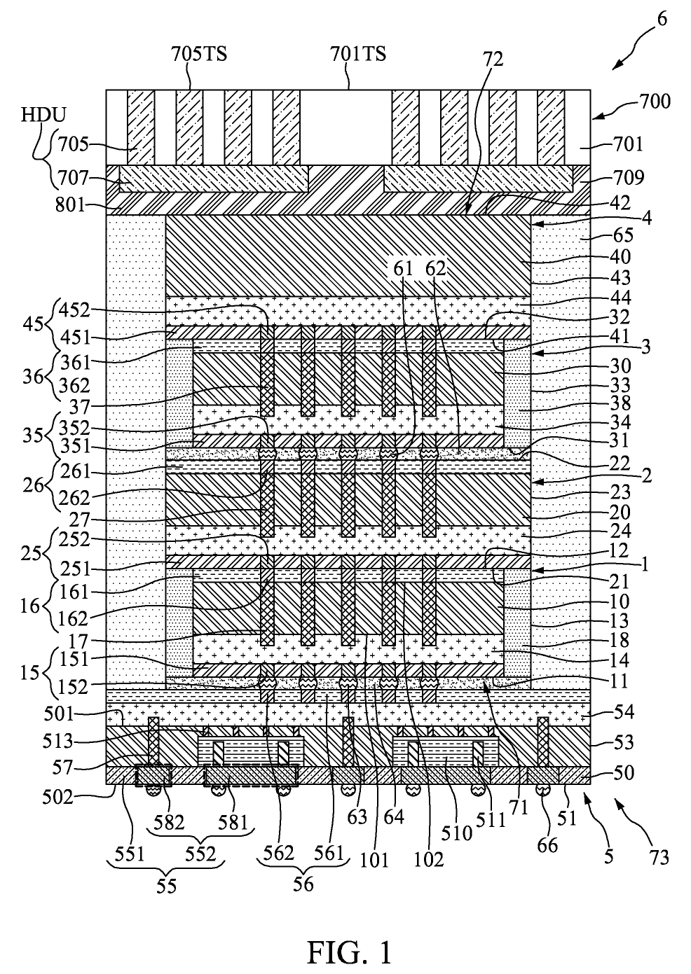

FIG. 1 is a schematic cross-sectional view of an electronic device 6 in accordance with some embodiments of the present disclosure. With reference to FIG. 1, in some embodiments, the electronic device 6 may be defined as a semiconductor electronic device or a semiconductor electronic structure including a plurality of semiconductor chips arranged in a stacked configuration. Accordingly, the electronic device 6 may be a stacked structure with a plurality of stacked memory devices, such as dynamic random-access memories (DRAMs). For example, the electronic device 6 may be a high-bandwidth memory (HBM). In some embodiments, the electronic device 6 may comprise a first assembly 71 (e.g., comprising a first semiconductor chip 1 and a second semiconductor chip 2), a second assembly 72 (e.g., comprising a third semiconductor chip 3 and a fourth semiconductor chip 4), a third assembly 73 (e.g., comprising a fifth semiconductor chip 5 and a plurality of external connectors 66), a plurality of bumps 61, an underfill 62, a plurality of electrical connectors 63, a protection material 64, a periphery encapsulant 65 and a carrier structure 700.

The first semiconductor chip 1 may have a bottom surface 11 (e.g., a first surface) and a top surface 12 (e.g., a second surface), and may have a side surface 13 that extends between the bottom surface 11 and the top surface 12. The first semiconductor chip 1 may comprise a first base portion 10, a first conductive structure 14, a first lower structure 15, a first upper structure 16, a plurality of first conductive vias 17 and a first encapsulant 18. The first semiconductor chip 1 may be a memory chip such as a dynamic random-access memory (DRAM) chip.

The first base portion 10 may be a semiconductor substrate and may be formed of, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP), another IV-IV, III-V or II-VI semiconductor materials. In some embodiments, the first base portion 10 may include a semiconductor-on-insulator substrate, such as a silicon-on-insulator (SOI) substrate, a silicon germanium-on-insulator (SGOI) substrate, or a germanium-on-insulator (GOI) substrate. The first base portion 10 may have a first surface 101 (e.g., a bottom surface) and a second surface 102 (e.g., a top surface) opposite to the first surface 101.

The first conductive structure 14 may be disposed on the first surface 101 (e.g., the bottom surface) of the first base portion 10. In some embodiments, the first conductive structure 14 may comprise a plurality of front-end-of-line (FEOL) devices comprising, for example, resistors, capacitors, inductors, diodes, p-type field-effect transistors (pFETs), n-type field-effect transistors (nFETs), metal-oxide-semiconductor field-effect transistors (MOSFETs), complementary metal-oxide semiconductor (CMOS) transistors, bipolar junction transistors (BJTs), laterally-diffused MOS (LDMOS) transistors, high-voltage transistors, high-frequency transistors, fin field-effect transistors (FinFETs), another suitable IC component, or a combination thereof. In some embodiments, the first conductive structure 14 may further comprise at least one back-end-of-line (BEOL) interconnect pattern, such as a plurality of patterned circuit layers, which are electrically connected to the FEOL devices. In some embodiments, the first conductive structure 14 may further comprise at least one dielectric layer or at least one dielectric structure that may be used to cover the FEOL devices and the BEOL interconnect pattern.

The first conductive vias 17 may extend through the first base portion 10 and may be electrically connected to the first conductive structure 14. In some embodiments, bottom ends of the first conductive vias 17 may extend beyond the first surface 101 (e.g., the bottom surface) of the first base portion 10 and may extend into the first conductive structure 14. In some embodiments, the first conductive via 17 may be a monolithic structure, and a length of the first conductive via 17 may be greater than a thickness of the first base portion 10. In some embodiments, a top surface of the first conductive via 17 may be substantially coplanar with the second surface 102 (e.g., the top surface) of the first base portion 10. In some embodiments, the top surface of the first conductive via 17 may be exposed by the second surface 102 (e.g., the top surface) of the first base portion 10.

The first lower structure 15 may be disposed on the first conductive structure 14. The first lower structure 15 may be a hybrid-bonded (HB) structure or a solder bonding structure and may comprise a first lower dielectric layer 151 and a plurality of first lower pads 152. The first lower dielectric layer 151 may be an HB dielectric layer and may include SiO₂, SiCN, and/or SiON. Each of the first lower pads 152 may be an HB pad and may include Cu or Al. The first lower pads 152 may be embedded in the first lower dielectric layer 15 and may be exposed by the first lower dielectric layer 151. The first lower pads 152 may be surrounded by the first lower dielectric layer 151. The first lower pads 152 may be electrically connected to the BEOL interconnect pattern of the first conductive structure 14. In some embodiments, the first lower pads 152 may be electrically connected to the first conductive vias 17 through the first conductive structure 14.

In some embodiments, a bottom surface of the first lower pad 152 may be substantially aligned with a bottom surface of the first lower dielectric layer 151. In some embodiments, the bottom surface of the first lower pad 152 may be exposed by the bottom surface of the first lower dielectric layer 151. In some embodiments, a top surface of the first lower pad 152 may be substantially aligned with a top surface of the first lower dielectric layer 151. In some embodiments, the top surface of the first lower pad 152 may contact the first conductive structure 14. In some embodiments, a thickness of the first lower pad 152 may be substantially equal to a thickness of the first lower dielectric layer 151.

The first upper structure 16 may be disposed on the second surface 102 (e.g., the top surface) of the first base portion 10. The first upper structure 16 may be an HB structure and may include a first upper dielectric layer 161 and a plurality of first upper pads 162.

The first upper dielectric layer 161 may be an HB dielectric layer and may include SiO₂, SiCN, and/or SiON. Each of the first upper pads 162 may be an HB pad and may include Cu or Al. The first upper pads 162 may be embedded in the first upper dielectric layer 161 and may be exposed by the first upper dielectric layer 161. The first upper pads 162 may be surrounded by the first upper dielectric layer 161. The first upper pads 162 may be electrically connected to the first conductive vias 17. In some embodiments, the first upper pads 162 may directly contact the first conductive vias 17. The first upper pads 162 may be electrically connected to the first lower pad 152 through the first conductive vias 17 and the first conductive structure 14.

In some embodiments, a top surface of the first upper pad 162 may be substantially aligned with a top surface of the first upper dielectric layer 161. In some embodiments, the top surface of the first upper pad 162 may be exposed by the top surface of the first upper dielectric layer 161. In some embodiments, a bottom surface of the first upper pad 162 may be substantially aligned with a bottom surface of the first upper dielectric layer 161. In some embodiments, the bottom surface of the first upper pad 162 may contact the first conductive via 17. In some embodiments, a thickness of the first upper pad 162 may be substantially equal to a thickness of the first upper dielectric layer 161.

The first encapsulant 18 may be disposed around the first base portion 10, the first conductive structure 14, the first lower structure 15 and the first upper structure 16. The first encapsulant 18 may comprise a molding compound with or without fillers. In some embodiments, a side surface of the first base portion 10, a side surface of the first conductive structure 14, a side surface of the first lower structure 15 and a side surface of the first upper structure 16 may be aligned or coplanar with each other. In some embodiments, the first encapsulant 18 may cover and contact the side surface of the first base portion 10, the side surface of the first conductive structure 14, the side surface of the first lower structure 15 and the side surface of the first upper structure 16.

In some embodiments, the bottom surface 11 of the first semiconductor chip 1 may include the bottom surface of the first lower pad 152, the bottom surface of the first lower dielectric layer 151 and a bottom surface of the first encapsulant 18. The top surface 12 of the first semiconductor chip 1 may include the top surface of the first upper pad 162, the top surface of the first upper dielectric layer 161 and a top surface of the first encapsulant 18. The side surface 13 of the first semiconductor chip 1 may be a side surface of the first encapsulant 18. In some embodiments, the first semiconductor chip 1 may not include the first encapsulant 18.

The second semiconductor chip 2 may be stacked on the first semiconductor chip 1 and may be electrically connected to the first semiconductor chip 1 by a hybrid bonding or a metal-to-metal bonding. The second semiconductor chip 2 may have a bottom surface 21 (e.g., a first surface) and a top surface 22 (e.g., a second surface), and may have a side surface 23 that extends between the bottom surface 21 and the top surface 22. The bottom surface 21 (e.g., the first surface) of the second semiconductor chip 2 may directly contact the top surface 12 of the first semiconductor chip 1. The side surface 23 of the second semiconductor chip 2 may be substantially aligned with or coplanar with the side surface 13 of the first semiconductor chip 1.

The second semiconductor chip 2 may include a second base portion 20, a second conductive structure 24, a second lower structure 25, a second upper structure 26 and a plurality of second conductive vias 27. The second semiconductor chip 2 may be a memory chip such as a dynamic random-access memory (DRAM) chip.

The second base portion 20 of the second semiconductor chip 2 may be same as or similar to the first base portion 10 of the first semiconductor chip 1. The second base portion 20 may be a semiconductor substrate, and may include, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP), or another IV-IV, III-V or II-VI semiconductor material. In some embodiments, the second base portion 20 may include a semiconductor-on-insulator substrate, such as a silicon-on-insulator (SOI) substrate, a silicon germanium-on-insulator (SGOI) substrate, or a germanium-on-insulator (GOI) substrate. The second base portion 20 may have a first surface (e.g., a bottom surface) and a second surface (e.g., a top surface) opposite to the first surface. As shown in FIG. 1, a width of the second base portion 20 of the second semiconductor chip 2 may be greater than a width of the first base portion 10 of the first semiconductor chip 1.

The second conductive structure 24 of the second semiconductor chip 2 may be same as or similar to the first conductive structure 14 of the first semiconductor chip 1. The second conductive structure 24 may be disposed on the first surface (e.g., the bottom surface) of the second base portion 20. In some embodiments, the second conductive structure 24 may comprise a plurality of FEOL devices, including, for examples, resistors, capacitors, inductors, diodes, p-type field-effect transistors (pFETs), n-type field-effect transistors (nFETs), metal-oxide semiconductor field-effect transistors (MOSFETs), complementary metal-oxide semiconductor (CMOS) transistors, bipolar junction transistors (BJTs), laterally-diffused MOS (LDMOS) transistors, high-voltage transistors, high-frequency transistors, fin field-effect transistors (FinFETs), another suitable IC components, or a combination thereof. In some embodiments, the second conductive structure 24 may further comprise at least one BEOL interconnect pattern, such as a plurality of patterned circuit layers, which are electrically connected to the FEOL devices. In some embodiments, the second conductive structure 24 may further comprise at least one dielectric layer or at least one dielectric structure covering the FEOL devices and the BEOL interconnect pattern. As shown in FIG. 1, a width of the second conductive structure 24 of the second semiconductor chip 2 may be greater than a width of the first conductive structure 14 of the first semiconductor chip 1.

The second conductive vias 27 may extend through the second base portion 20 and may be electrically connected to the second conductive structure 24. In some embodiments, bottom ends of the second conductive vias 27 may extend beyond the first surface (e.g., the bottom surface) of the second base portion 20 and may extend into the second conductive structure 24. In some embodiments, the second conductive via 27 may be a monolithic structure, and a length of the second conductive via 27 may be greater than a thickness of the second base portion 20. In some embodiments, a top surface of the second conductive via 27 may be substantially coplanar with the second surface (e.g., the top surface) of the second base portion 20. In some embodiments, the top surface of the second conductive via 27 may be exposed by the second surface (e.g., the top surface) of the second base portion 20.

The second lower structure 25 of the second semiconductor chip 2 may be same as or similar to the first lower structure 15 of the first semiconductor chip 1. The second lower structure 25 may be disposed on the second conductive structure 24. The second lower structure 25 may be a HB structure and may comprise a second lower dielectric layer 251 and a plurality of second lower pads 252. The second lower dielectric layer 251 may be a HB dielectric layer, and may include SiO₂, SiCN and/or SiON. Each of the second lower pads 252 may be a HB pad, and may include Cu or Al. The second lower pads 252 may be embedded in the second lower dielectric layer 251 and may be exposed by the second lower dielectric layer 251. The second lower pads 252 may be surrounded by the second lower dielectric layer 251. The second lower pads 252 may be electrically connected to the BEOL interconnect pattern of the second conductive structure 24. In some embodiments, the second lower pads 252 may be electrically connected to the second conductive vias 27 through the second conductive structure 24.

In some embodiments, a bottom surface of the second lower pad 252 may be substantially aligned with a bottom surface of the second lower dielectric layer 251. In some embodiments, the bottom surface of the second lower pad 252 may be exposed by the bottom surface of the second lower dielectric layer 251. In some embodiments, a top surface of the second lower pad 252 may be substantially aligned with a top surface of the second lower dielectric layer 251. In some embodiments, the top surface of the second lower pad 252 may contact the second conductive structure 24. In some embodiments, a thickness of the second lower pad 252 may be substantially equal to a thickness of the second lower dielectric layer 251.

As shown in FIG. 1, a width of the second lower structure 25 of the second semiconductor chip 2 may be greater than a width of the first lower structure 15 of the first semiconductor chip 1. The second lower structure 25 of the second semiconductor chip 2 may be bonded to and electrically connected to the first upper structure 16 of the first semiconductor chip 1 through hybrid bonding. For example, the second lower dielectric layer 251 of the second semiconductor chip 2 may be attached to, bonded to or adhered to the first upper dielectric layer 161 and the first encapsulant 18 of the first semiconductor chip 1. The second lower dielectric layer 251 of the second semiconductor chip 2 may be bonded to the first upper dielectric layer 161 of the first semiconductor chip 1 through a dielectric-to-dielectric bonding. In some embodiments, the second semiconductor chip 2 may directly contact the first encapsulant 18 of the first semiconductor chip 1.

The second lower pad 252 of the second semiconductor chip 2 may be attached to, joined to, or electrically connected to the first upper pad 162 of the first semiconductor chip 1 through a metal-to-metal bonding. In some embodiments, the second lower pad 252 of the second semiconductor chip 2 may directly contact the first upper pad 162 of the first semiconductor chip 1. A width of the second lower pad 252 of the second semiconductor chip 2 may be substantially equal to a width of the first upper pad 162 of the first semiconductor chip 1. The second semiconductor chip 2 and the first semiconductor chip 1 may be in a face-to-face contact.

The second upper structure 26 of the second semiconductor chip 2 may be same as or similar to the first upper structure 16 of the first semiconductor chip 1. The second upper structure 26 may be disposed on the second surface (e.g., the top surface) of the second base portion 20. The second upper structure 26 may be a HB structure or a solder bonding structure and may include a second upper dielectric layer 261 and a plurality of second upper pads 262.

The second upper dielectric layer 261 may be a HB dielectric layer, and may include SiO₂, SiCN and/or SiON. Each of the second upper pads 262 may be a HB pad, and may include Cu or Al. The second upper pads 262 may be embedded in the second upper dielectric layer 261, and may be exposed by the second upper dielectric layer 261. The second upper pads 262 may be surrounded by the second upper dielectric layer 261. The second upper pads 262 may be electrically connected to the second conductive vias 27. In some embodiments, the second upper pads 262 may directly contact the second conductive vias 27. The second upper pads 262 may be electrically connected to the second lower pad 252 through the second conductive vias 27 and the second conductive structure 24.

In some embodiments, a top surface of the second upper pad 262 may be substantially aligned with a top surface of the second upper dielectric layer 261. In some embodiments, the top surface of the second upper pad 262 may be exposed by the top surface of the second upper dielectric layer 261. In some embodiments, a bottom surface of the second upper pad 262 may be substantially aligned with a bottom surface of the second upper dielectric layer 261. In some embodiments, the bottom surface of the second upper pad 262 may contact the second conductive via 27. In some embodiments, a thickness of the second upper pad 262 may be substantially equal to a thickness of the second upper dielectric layer 261.

In some embodiments, the bottom surface 21 of the second semiconductor chip 2 may include the bottom surface of the second lower pad 252 and the bottom surface of the second lower dielectric layer 251. The top surface 22 of the second semiconductor chip 2 may include the top surface of the second upper pad 262 and the top surface of the second upper dielectric layer 261. The side surface 23 of the second semiconductor chip 2 may include a side surface of the second base portion 20, a side surface of the second conductive structure 24, a side surface of the second lower structure 25 and a side surface of the second upper structure 26. In some embodiments, the side surface of the second base portion 20, the side surface of the second conductive structure 24, the side surface of the second lower structure 25 and the side surface of the second upper structure 26 may be aligned or coplanar with each other.

The second assembly 72 may be stacked on the first assembly 71. The second assembly 72 may be spaced apart from the first assembly 71. The second assembly 72 may include a third semiconductor chip 3 and a fourth semiconductor chip 4 stacked on the third semiconductor chip 3 and electrically connected to the third semiconductor chip 3 by a hybrid bonding. The second assembly 72 may be electrically connected to the first assembly 71 through the bumps 61. The bumps 61 may include a reflowable material such as AgSn. In some embodiments, the bumps 61 may include solder balls, solder bumps or microbumps. In addition, the underfill 62 may be disposed between the second assembly 72 and the first assembly 71, and may cover the bumps 61.

The third semiconductor chip 3 may be stacked on the second semiconductor chip 2 and may be electrically connected to the second semiconductor chip 2 through the bumps 61. The third semiconductor chip 3 may have a bottom surface 31 (e.g., a first surface) and a top surface 32 (e.g., a second surface), and may have a side surface 33 that extends between the bottom surface 31 and the top surface 32. The bottom surface 31 (e.g., the first surface) of the third semiconductor chip 3 may be spaced apart from the top surface 22 of the second semiconductor chip 2. The underfill 62 may be disposed between the bottom surface 31 of the third semiconductor chip 3 and the top surface 22 of the second semiconductor chip 2 to cover the bumps 61.

The third semiconductor chip 3 may be same as or similar to the first semiconductor chip 1. The third semiconductor chip 3 may comprise a third base portion 30, a third conductive structure 34, a third lower structure 35, a third upper structure 36, a plurality of third conductive vias 37, and a third encapsulant 38. The third semiconductor chip 3 may be a memory chip such as a dynamic random-access memory (DRAM) chip.

The third base portion 30 of the third semiconductor chip 3 may be same as or similar to the first base portion 10 of the first semiconductor chip 1. The third base portion 30 may have a first surface (e.g., a bottom surface) and a second surface (e.g., a top surface) opposite to the first surface. As shown in FIG. 1, a width of the third base portion 30 of the third semiconductor chip 3 may be substantially equal to the width of the first base portion 10 of the first semiconductor chip 1.

The third conductive structure 34 of the third semiconductor chip 3 may be same as or similar to the first conductive structure 14 of the first semiconductor chip 1. The third conductive structure 34 may be disposed on the first surface (e.g., the bottom surface) of the third base portion 30. In some embodiments, the third conductive structure 34 may comprise a plurality of FEOL devices and at least one BEOL interconnect pattern. As shown in FIG. 1, a width of the third conductive structure 34 of the third semiconductor chip 3 may be substantially equal to the first conductive structure 14 of the first semiconductor chip 1.

The third conductive vias 37 may extend through the third base portion 30 and may be electrically connected to the third conductive structure 34. In some embodiments, bottom ends of the third conductive vias 37 may extend beyond the first surface (e.g., the bottom surface) of the third base portion 30 and may extend into the third conductive structure 34. In some embodiments, a top surface of the third conductive via 37 may be substantially coplanar with the second surface (e.g., the top surface) of the third base portion 30.

The third lower structure 35 of the third semiconductor chip 3 may be same as or similar to the first lower structure 15 of the first semiconductor chip 1. The third lower structure 35 may be disposed on the third conductive structure 34. The third lower structure 35 may be an HB structure or a solder bonding structure and may include a third lower dielectric layer 351 and a plurality of third lower pads 352. The third lower dielectric layer 351 may be an HB dielectric layer and may include SiO₂, SiCN, and/or SiON. Each of the third lower pads 352 may be an HB pad and may include Cu or Al. The third lower pads 352 may be embedded in the third lower dielectric layer 351 and may be exposed by the third lower dielectric layer 351. The third lower pads 352 may be electrically connected to the BEOL interconnect pattern of the third conductive structure 34. In some embodiments, the third lower pads 352 may be electrically connected to the third conductive vias 37 through the third conductive structure 34.

As shown in FIG. 1, a width of the third lower structure 35 of the third semiconductor chip 3 may be substantially equal to the width of the first lower structure 15 of the first semiconductor chip 1. The third lower pads 352 of the third lower structure 35 of the third semiconductor chip 3 may be bonded to and electrically connected to the second upper pads 262 of the second upper structure 26 of the second semiconductor chip 2 through the bumps 61.

The third upper structure 36 of the third semiconductor chip 3 may be same as or similar to the first upper structure 16 of the first semiconductor chip 1. The third upper structure 36 may be disposed on the second surface (e.g., the top surface) of the third base portion 30. The third upper structure 36 may be an HB structure and may comprise a third upper dielectric layer 361 and a plurality of third upper pads 362.

The third upper dielectric layer 361 may be an HB dielectric layer and may include SiO₂, SiCN, and/or SiON. Each of the third upper pads 362 may be an HB pad and may include Cu or Al. The third upper pads 362 may be embedded in the third upper dielectric layer 361 and may be exposed by the third upper dielectric layer 361. The third upper pads 362 may be electrically connected to the third conductive vias 37. In some embodiments, the third upper pads 362 may be electrically connected to the third lower pad 352 through the third conductive vias 37 and the third conductive structure 34.

The third encapsulant 38 of the third semiconductor chip 3 may be same as or similar to the first encapsulant 18 of the first semiconductor chip 1. The third encapsulant 38 may be disposed around the third base portion 30, the third conductive structure 34, the third lower structure 35 and the third upper structure 36. The third encapsulant 38 may cover and contact the side surface of the third base portion 30, the side surface of the third conductive structure 34, the side surface of the third lower structure 35 and the side surface of the third upper structure 36.

In some embodiments, the bottom surface 31 of the third semiconductor chip 3 may include the bottom surface of the third lower pad 352, the bottom surface of the third lower dielectric layer 351 and a bottom surface of the third encapsulant 38. The top surface 32 of the third semiconductor chip 3 may include the top surface of the third upper pad 362, the top surface of the third upper dielectric layer 361 and a top surface of the third encapsulant 38. The side surface 33 of the third semiconductor chip 3 may be a side surface of the third encapsulant 38. In some embodiments, the third semiconductor chip 3 may not include the third encapsulant 38.

The fourth semiconductor chip 4 may be stacked on the third semiconductor chip 3 and may be electrically connected to the third semiconductor chip 3 by a hybrid bonding or a metal-to-metal bonding. The fourth semiconductor chip 4 may have a bottom surface 41 (e.g., a first surface) and a top surface 42 (e.g., a second surface), and may have a side surface 43 that extends between the bottom surface 41 and the top surface 42. The bottom surface 41 (e.g., the first surface) of the fourth semiconductor chip 4 may directly contact the top surface 32 of the third semiconductor chip 3. The side surface 43 of the fourth semiconductor chip 4 may be substantially aligned with or coplanar with the side surface 33 of the third semiconductor chip 3.

The fourth semiconductor chip 4 may be same as or similar to the second semiconductor chip 2. The fourth semiconductor chip 4 may include a fourth base portion 40, a fourth conductive structure 44 and a fourth lower structure 45. The fourth semiconductor chip 4 may be a memory chip such as a dynamic random-access memory (DRAM) chip.

The fourth base portion 40 of the fourth semiconductor chip 4 may be same as or similar to the second base portion 20 of the second semiconductor chip 2. As shown in FIG. 1, a width of the fourth base portion 40 of the fourth semiconductor chip 4 may be greater than the width of the third base portion 30 of the third semiconductor chip 3. A thickness of the fourth base portion 40 of the fourth semiconductor chip 4 may be greater than a thickness of the third base portion 30 of the third semiconductor chip 3.

The fourth conductive structure 44 of the fourth semiconductor chip 4 may be same as or similar to the second conductive structure 24 of the second semiconductor chip 2. The fourth conductive structure 44 may be disposed on the first surface (e.g., the bottom surface) of the fourth base portion 40. In some embodiments, the fourth conductive structure 44 may comprise a plurality of FEOL devices and at least one BEOL interconnect pattern. As shown in FIG. 1, a width of the fourth conductive structure 44 of the fourth semiconductor chip 4 may be greater than a width of the third conductive structure 34 of the third semiconductor chip 3.

The fourth semiconductor chip 4 may or may not include conductive vias that extend in the fourth base portion 40 and are electrically connected to the fourth conductive structure 44.

The fourth lower structure 45 of the fourth semiconductor chip 4 may be same as or similar to the third lower structure 35 of the third semiconductor chip 3. The fourth lower structure 45 may be disposed on the fourth conductive structure 44. The fourth lower structure 45 may be an HB structure and may comprise a fourth lower dielectric layer 451 and a plurality of fourth lower pads 452. The fourth lower dielectric layer 451 may be an HB dielectric layer and may include SiO₂, SiCN and/or SiON. Each of the fourth lower pads 452 may be an HB pad and may include Cu or Al. The fourth lower pads 452 may be embedded in the fourth lower dielectric layer 451 and may be exposed by the fourth lower dielectric layer 451. The fourth lower pads 452 may be electrically connected to the BEOL interconnect pattern of the fourth conductive structure 44.

As shown in FIG. 1, a width of the fourth lower structure 45 of the fourth semiconductor chip 4 may be greater than the width of the third lower structure 35 of the third semiconductor chip 3. The fourth lower structure 45 of the fourth semiconductor chip 4 may be bonded to and electrically connected to the third upper structure 36 of the third semiconductor chip 3 through hybrid bonding. For example, the fourth lower dielectric layer 451 of the fourth semiconductor chip 4 may be attached to, bonded to or adhered to the third upper dielectric layer 361 and the third encapsulant 38 of the third semiconductor chip 3. The fourth lower dielectric layer 451 of the fourth semiconductor chip 4 may be bonded to the third upper dielectric layer 361 of the third semiconductor chip 3 through a dielectric-to-dielectric bonding. Thus, the fourth semiconductor chip 4 may directly contact the third encapsulant 38 of the third semiconductor chip 3.

The fourth lower pad 452 of the fourth semiconductor chip 4 may be attached to, joined to, or electrically connected to the third upper pad 362 of the third semiconductor chip 3 through a metal-to-metal bonding. The fourth semiconductor chip 4 and the third semiconductor chip 3 may be in face-to-face contact.

In some embodiments, the bottom surface 41 of the fourth semiconductor chip 4 may include the bottom surface of the fourth lower pad 452 and the bottom surface of the fourth lower dielectric layer 451. The top surface 42 of the fourth semiconductor chip 4 may include the second surface (e.g., the top surface) of the fourth base portion 40.

The third assembly 73 may be stacked below the first assembly 71. The third assembly 73 may comprise a fifth semiconductor chip 5 and a plurality of external connectors 66. In some embodiments, the third assembly 73 may not include the external connectors 66.

The fifth semiconductor chip 5 may have a bottom surface 51 (e.g., a first surface) and a top surface 52 (e.g., a second surface), and may have a side surface 53 that extends between the bottom surface 51 and the top surface 52. The fifth semiconductor chip 5 may comprise a fifth base portion 50, a fifth conductive structure 54, a plurality of fifth conductive vias 57, a fifth lower structure 55, a fifth upper structure 56 and a plurality of fifth dies 510. The fifth semiconductor chip 5 may be a controller chip such as an application processor (AP) chip.

The fifth base portion 50 may be a semiconductor substrate, and may include, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP), or another IV-IV, III-V or II-VI semiconductor material. The fifth base portion 50 may have a first surface 501 (e.g., a top surface) and a second surface 502 (e.g., a bottom surface) opposite to the first surface 501.

The fifth conductive structure 54 may be disposed on the first surface 501 (e.g., the top surface) of the fifth base portion 50. In some embodiments, the fifth conductive structure 54 may comprise a plurality of FEOL devices and at least one BEOL interconnect pattern.

The fifth lower structure 55 may be disposed on the fifth base portion 50. The fifth lower structure 55 may comprise a passivation layer 551 and a conductive layer 552, wherein the conductive layer 552 comprises a first portion 581 and a second portion 582. A bottom surface of the passivation layer 551 may be substantially aligned with the bottom surface 51 (e.g., the first surface) of the fifth semiconductor chip 5. The conductive layer 552 may be embedded in the passivation layer 551 and may be exposed by the passivation layer 551. In some embodiments, the conductive layer 552 may be surrounded by the passivation layer 551. In some embodiments, the conductive layer 552 may be electrically connected to the external connectors 66. In some embodiments, the conductive layer 552 may be electrically connected to the fifth conductive vias 57.

In some embodiments, a bottom surface of the conductive layer 552 may be substantially aligned with a bottom surface of the passivation layer 551. In some embodiments, the bottom surface of the conductive layer 552 may be exposed by the bottom surface of the passivation layer 551. In some embodiments, a top surface of the conductive layer 552 may be substantially aligned with a top surface of the passivation layer 551. In some embodiments, the top surface of the conductive layer 552 may contact the fifth base portion 50 and the fifth conductive via 57. In some embodiments, a thickness of the conductive layer 552 may be substantially equal to a thickness of the passivation layer 551.

The fifth upper structure 56 may be disposed on the fifth conductive structure 54. The fifth upper structure 56 may be an HB structure or a solder bonding structure and may include a fifth upper dielectric layer 561 and a plurality of fifth upper pads 562. The fifth upper dielectric layer 561 may be an HB dielectric layer and may include SiO₂, SiCN, and/or SiON. Each of the fifth upper pads 562 may be an HB pad, and may include Cu or Al. The fifth upper pads 562 may be embedded in the fifth upper dielectric layer 561 and may be exposed by the fifth upper dielectric layer 561. The fifth upper pads 562 may be electrically connected to the BEOL interconnect pattern of the fifth conductive structure 54.

The fifth conductive vias 57 may extend through the fifth base portion 50 and may be electrically connected to the fifth conductive structure 54 and the first portion 581 of the conductive layer 552. In some embodiments, an end of the fifth conductive via 57 may extend into the fifth conductive structure 54.

The fifth dies 510 may be disposed in the second surface 502 (e.g., the bottom surface) of the base portion, wherein each of the fifth dies 510 may comprise a plurality of contact pads 513 disposed on the fifth die and connected to the fifth conductive structure 54, and may comprise a plurality of conductive lines 511 disposed in a bottom surface of the fifth die and connected to first portion 581 of the conductive layer 552.

The external connectors 66 may be disposed on the bottom surface 51 of the fifth semiconductor chip 5 for external connection. The external connectors 66 may include a reflowable material such as AgSn. In some embodiments, the external connectors 66 may include solder balls, solder bumps, or micro-bumps. The external connectors 66 may be disposed on the conductive layer 552 of the fifth lower structure 55 of the fifth semiconductor chip 5.

In some embodiments, the bottom surface 51 of the fifth semiconductor chip 5 may include the bottom surface of the passivation layer 551 and the bottom surface of the conductive layer 552. The top surface 52 of the fifth semiconductor chip 5 may include the top surface of the fifth upper pad 562 and the top surface of the fifth upper dielectric layer 561.

The first lower pads 152 of the first lower structure 15 of the first semiconductor chip 1 may be bonded to and electrically connected to the fifth upper pad 562 of the fifth upper structure 56 of the fifth semiconductor chip 5 through the electrical connectors 63. The electrical connectors 63 may include a reflowable material such as AgSn. In some embodiments, the electrical connectors 63 may include solder balls, solder bumps or micro-bumps. In addition, the protection material 64 (e.g., an underfill) may be disposed between the first semiconductor chip 1 and the fifth semiconductor chip 5 and may cover the electrical connectors 63.

The periphery encapsulant 65 may be a molding compound with or without fillers. The periphery encapsulant 65 may encapsulate the first semiconductor chip 1, the second semiconductor chip 2, the third semiconductor chip 3, the fourth semiconductor chip 4 and the fifth semiconductor chip 5. The periphery encapsulant 65 may cover the side surface 13 of the first semiconductor chip 1, the side surface 23 of the second semiconductor chip 2, the side surface 33 of the third semiconductor chip 3, the side surface 43 of the fourth semiconductor chip 4 and the top surface 52 of the fifth semiconductor chip 5.

As mentioned above, in some embodiments, the third assembly 73 may not comprise the external connectors 66. In such a case, prior to the formation of the external connectors 66, an encapsulating operation using the periphery encapsulant 65 as an encapsulant may be performed.

The carrier structure 700 may be disposed over the second assembly 72 and periphery encapsulant 65. The carrier structure 700 may comprise a carrier substrate 701, a heat dissipation unit HDU and a bonding layer 709.

The carrier substrate 701 may be formed of, for example, silicon, germanium, silicon germanium, silicon carbon, silicon germanium carbon, gallium, gallium arsenide, indium arsenide, indium phosphorus or another IV-IV, III-V or II-VI semiconductor materials.

The HDU may comprise a plurality of conductive plates 707 and a plurality of through semiconductor vias (TSVs) 705. The TSVs 705 may be disposed in the carrier substrate 701. In some embodiments, sidewalls of the TSVs 705 may be slightly tapered such as between about 85 degrees and about 88 degrees. In some embodiments, widths of the TSVs 705 may be between about 1 μm and about 22 μm or between about 5 μm and about 15 μm. In some embodiments, the depths of the through semiconductor vias 705 may be between about 20 μm and about 160 μm or between about 50 μm and about 130 μm. The conductive plates 707 may be formed on the carrier substrate 701 and separated from each other. Each one of the conductive plates 707 may connect to two or more TSVs 705. The conductive plates 707 may be formed of, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. The conductive plates 707 and the TSVs 705 together configure the heat dissipation unit HDU.

In some embodiments, only one conductive plate 707 may be formed on the carrier substrate 701 and connect to all the TSVs 705. In some embodiments, top surfaces 705TS of the TSVs 705 of the carrier structure 700 and a top surface 701TS of the carrier substrate 701 are substantially coplanar.

The bonding layer 709 may be disposed on the carrier substrate 701 covering the conductive plates 707. In some embodiments, the bonding layer 709 may be formed of, for example, a non-organic material selected from un-doped silicate glass, silicon nitride, silicon oxynitride, silicon oxide, silicon nitride oxide, or a combination thereof. In some embodiments, the bonding layer 709 may be formed of, for example, a polymer layer such as epoxy, polyimide, benzocyclobutene, polybenzoxazole, or the like.

In some embodiments, the electronic device 6 further comprises an intervening bonding layer 801 disposed between the second assembly 72 and the bonding layer 709 and between the periphery encapsulant 65 and the bonding layer 709. In some embodiments, the intervening bonding layer 801 may be formed of a same material as the bonding layer 709, but is not limited thereto. In some embodiments, the intervening bonding layer 801 may be formed of, for example, a non-organic material selected from un-doped silicate glass, silicon nitride, silicon oxynitride, silicon oxide, silicon nitride oxide, and a combination thereof. In some embodiments, the intervening bonding layer 801 may be formed of, for example, a polymer layer such as epoxy, polyimide, benzocyclobutene, polybenzoxazole, or the like.

In accordance with the embodiment of the present disclosure illustrated in FIG. 1, during an operation of the electronic device 6, a heat accumulated in the operation is thermally conducted to the ambient through the conductive plates 707 and the semiconductor vias 705 (i.e., the heat dissipation unit HDU). As a result, a thermal conducting capability of the electronic device 6 is improved.

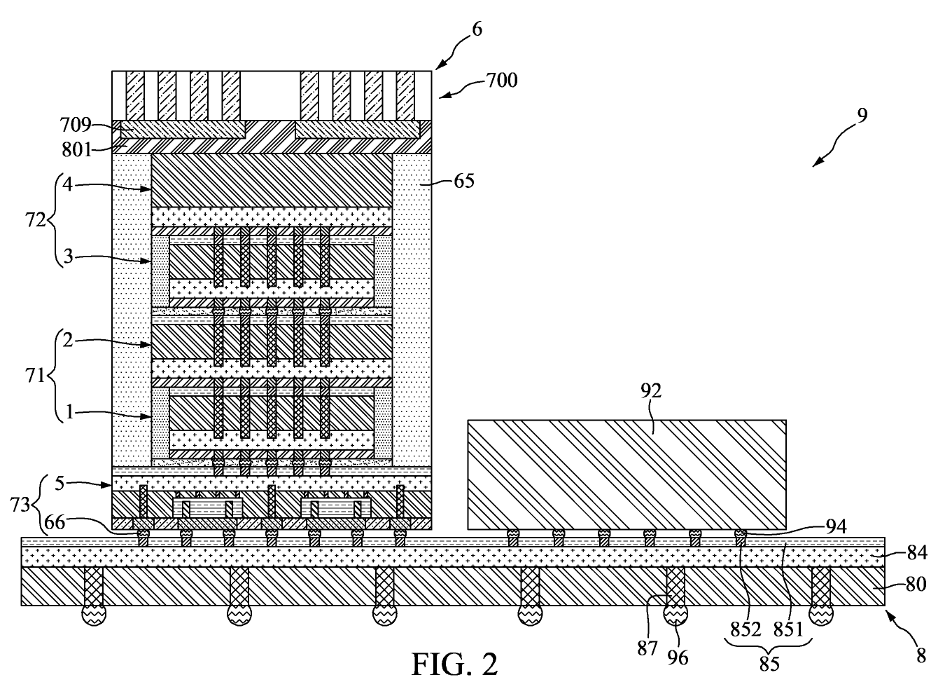

FIG. 2 is a schematic cross-sectional view of a semiconductor structure 9 in accordance with some embodiments of the present disclosure. The semiconductor structure 9 may include an interposer 8, an electronic device 6, a semiconductor device 92 and a plurality of external connectors 96.

The interposer 8 may include a base portion 80, a conductive structure 84, an upper structure 85 and a plurality of conductive vias 87. The base portion 80 may be a semiconductor substrate and may include, for example, silicon (Si), doped silicon, germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP) or other IV-IV, III-V or II-VI semiconductor materials.

The conductive structure 84 may be disposed on the base portion 80. In some embodiments, the conductive structure 84 may include a redistribution layer (RDL) structure. The conductive vias 87 may extend through the base portion 80 and may be electrically connected to the conductive structure 84.

The upper structure 85 may be disposed on the conductive structure 84. The upper structure 85 may include a dielectric layer 851 and a plurality of pads 852. The dielectric layer 851 may be a solder mask layer. The pads 852 may be embedded in the dielectric layer 851 and may be exposed by the dielectric layer 851.

The external connectors 96 may be disposed on the bottom surface of the interposer 8 for external connection. The external connectors 96 may include a reflowable material such as AgSn. Thus, the external connectors 96 may include solder balls, solder bumps or micro-bumps. The external connectors 96 may be disposed on the conductive vias 87.

The electronic device 6 of FIG. 2 may be the electronic device 6 of FIG. 1. The electronic device 6 may be bonded to and electrically connected to the pads 852 of the interposer 8 through the external connectors 66.

The semiconductor device 92 may be a logic chip or a logic die. The semiconductor device 92 may be bonded to and electrically connected to the pads 852 of the interposer 8 through a plurality of solders 94. Thus, the electronic device 6 may be electrically connected to the semiconductor device 92 through the interposer 8.

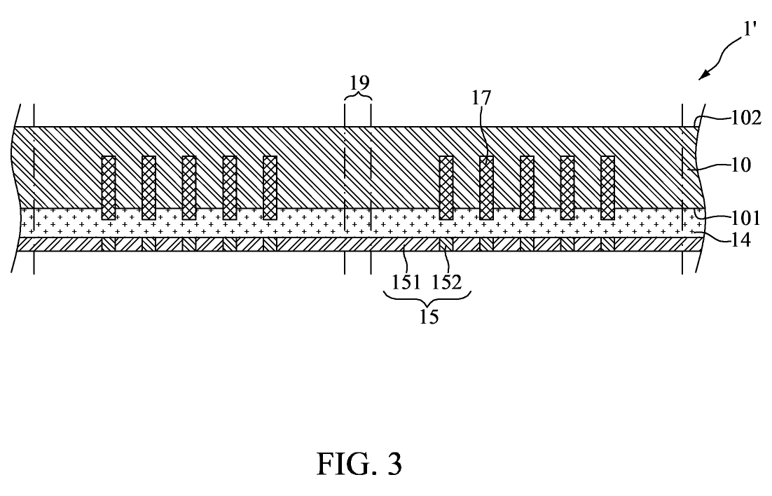

FIGS. 3 to 28 are various stages of a method of manufacturing an electronic device in accordance with some embodiments of the present disclosure.

With reference to FIGS. 3 to 11, a first assembly 71 comprising a first semiconductor chip 1 and a second semiconductor chip 2 may be provided. The manufacturing of the first assembly 71 is described below.

Referring to FIG. 3, a first wafer 1' may be provided. The first wafer 1' may comprise a first base portion 10, a first conductive structure 14, a first lower structure 15 and a plurality of first conductive vias 17. The first base portion 10, the first conductive structure 14, the first lower structure 15 and the first conductive vias 17 of FIG. 3 may be same as or similar to the first base portion 10, the first conductive structure 14, the first lower structure 15 and the first conductive vias 17 of FIG. 1, respectively. The first wafer 1' may define a plurality of singulation lines 19. The first base portion 10 may have a first surface 101 (e.g., a bottom surface) and a second surface 102 (e.g., a top surface) opposite to the first surface 101.

The first conductive structure 14 may be disposed on the first surface 101 (e.g., the bottom surface) of the first base portion 10. The first conductive vias 17 may extend in the first base portion 10 and may be electrically connected to the first conductive structure 14. The first lower structure 15 may be disposed on the first conductive structure 14. The first lower structure 15 may comprise a first lower dielectric layer 151 and a plurality of first lower pads 152. The first lower pads 152 may be embedded in the first lower dielectric layer 151 and may be exposed by the first lower dielectric layer 151.

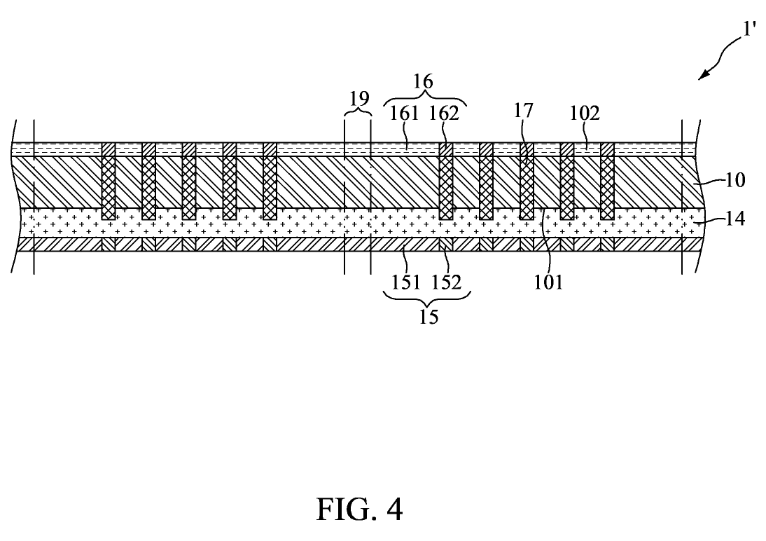

Referring to FIG. 4, the first base portion 10 may be thinned from the second surface 102 (e.g., the top surface) such that the first conductive vias 17 can be exposed. Next, a first upper structure 16 may be formed on the second surface 102 of the first base portion 10. The first upper structure 16 may include a first upper dielectric layer 161 and a plurality of first upper pads 162. The first upper pads 162 may be embedded in the first upper dielectric layer 161 and may be exposed by the first upper dielectric layer 161. The first upper pads 162 may be electrically connected to the first conductive vias 17.

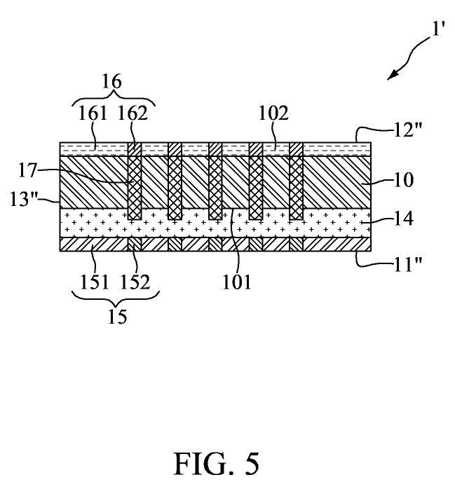

Referring to FIG. 5, the first wafer 1' may be divided along the singulation lines 19 to form a plurality of units 1". The unit 1" has a bottom surface 11" (e.g., a first surface) and a top surface 12" (e.g., a second surface), and has a side surface 13" that extends between the bottom surface 11" and the top surface 12".

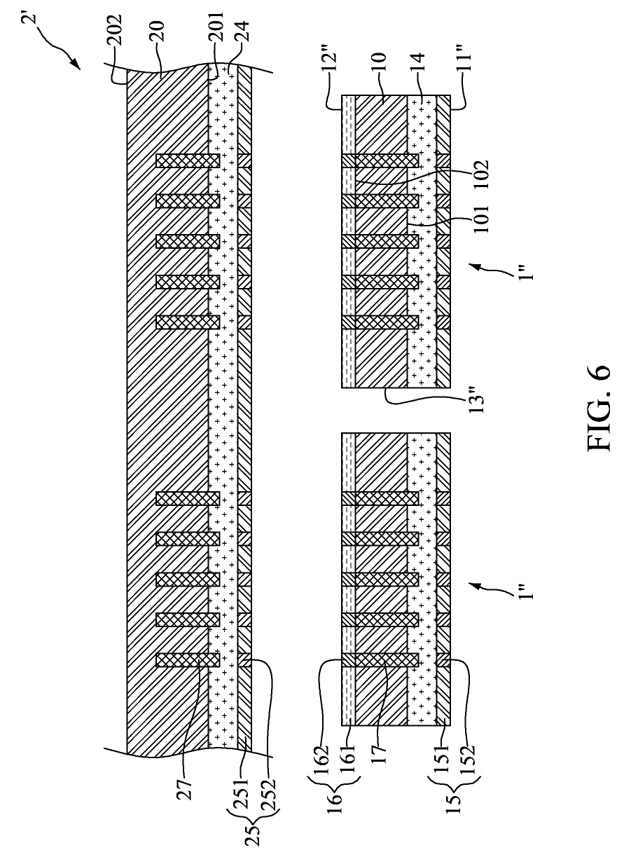

Referring to FIG. 6, a second wafer 2' may be provided. The second wafer 2' may comprise a second base portion 20, a second conductive structure 24, a second lower structure 25 and a plurality of second conductive vias 27. The second base portion 20, the second conductive structure 24, the second lower structure 25 and the second conductive vias 27 of FIG. 6 may be same as or similar to the second base portion 20, the second conductive structure 24, the second lower structure 25 and the second conductive vias 27 of FIG. 1, respectively. The second base portion 20 may have a first surface 201 (e.g., a bottom surface) and a second surface 202 (e.g., a top surface) opposite to the first surface 201.

The second conductive structure 24 may be disposed on the first surface 201 (e.g., a bottom surface) of the second base portion 20. The second conductive vias 27 may extend in the second base portion 20 and may be electrically connected to the second conductive structure 24. The second lower structure 25 may be disposed on the second conductive structure 24. The second lower structure 25 may comprise a second lower dielectric layer 251 and a plurality of second lower pads 252. The second lower pads 252 may be embedded in the second lower dielectric layer 251 and may be exposed by the second lower dielectric layer 251.

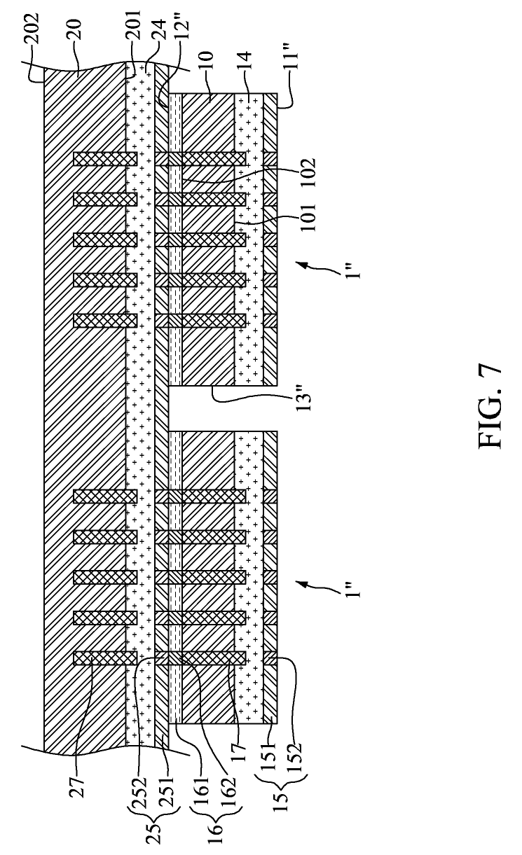

Referring to FIG. 7, a plurality of units 1" may be attached to the second wafer 2' through a hybrid bonding. The first upper dielectric layer 161 of the unit 1" may be attached to, bonded to or adhered to the second lower dielectric layer 251 of the second wafer 2' through a dielectric-to-dielectric bonding. The first upper pad 162 of the unit 1" may be attached to, joined to, or electrically connected to the second lower pad 252 of the second wafer 2' through a metal-to-metal bonding.

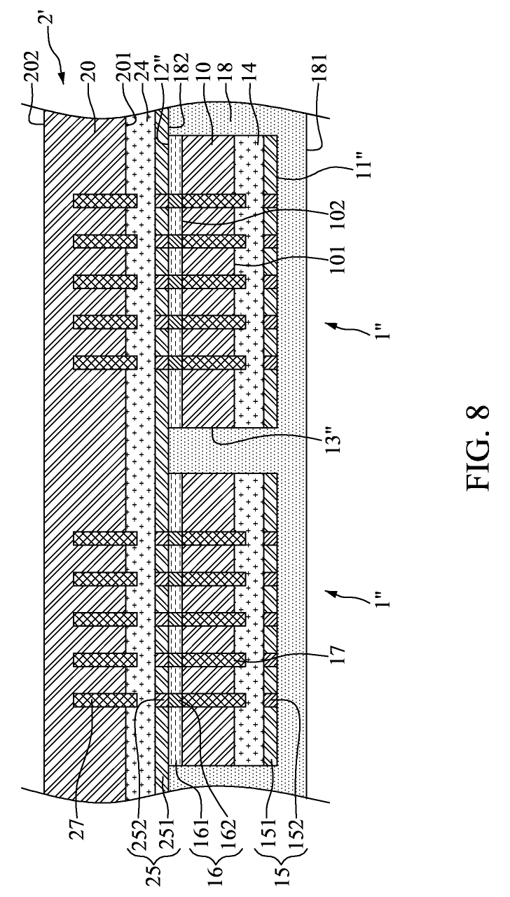

Referring to FIG. 8, a first encapsulant 18 may be formed or disposed on the second lower structure 25 to cover the units 1". The first encapsulant 18 may have a first surface 181 (e.g., a bottom surface) and a second surface 182 (e.g., a top surface) opposite to the first surface 181. The first surface 181 of the first encapsulant 18 may be lower than the bottom surface 11" of the unit 1". The second surface 182 of the first encapsulant 18 may contact the second lower structure 25. In some embodiments, the first encapsulant 18 may cover the side surface 13" and the bottom surface 11" of the unit 1".

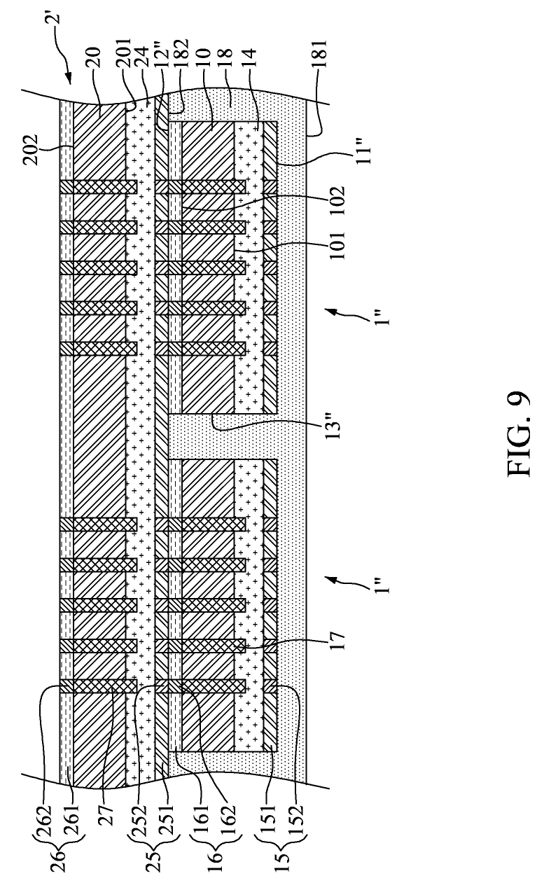

Referring to FIG. 9, the second base portion 20 may be thinned from the second surface 202 (e.g., the top surface) such that the second conductive vias 27 may be exposed. Next, a second upper structure 26 may be formed on the second surface 202 of the second base portion 20. The second upper structure 26 may comprise a second upper dielectric layer 261 and a plurality of second upper pads 262. The second upper pads 262 may be embedded in the second upper dielectric layer 261, and may be exposed by the second upper dielectric layer 261. The second upper pads 262 may be electrically connected to the second conductive vias 27.

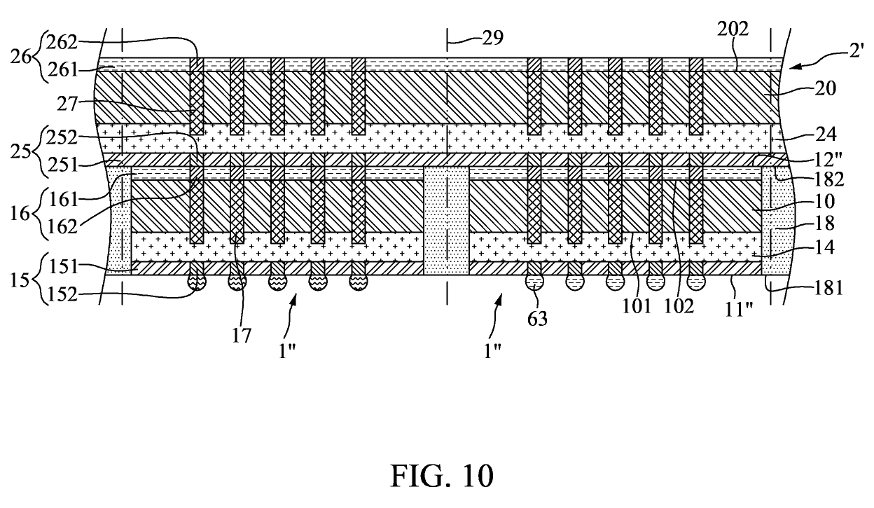

Referring to FIG. 10, the first encapsulant 18 may be thinned from the first surface 181 (e.g., the bottom surface) to expose the units 1". The first surface 181 (e.g., the bottom surface) of the first encapsulant 18 may be substantially coplanar with the bottom surfaces 11" of the units 1". Next, a plurality of electrical connectors 63 may be formed or disposed on the first lower pads 152 of the first lower structure 15 of the unit 1". The electrical connectors 63 may include a reflowable material such as AgSn. Meanwhile, the second wafer 2' and the first encapsulant 18 may define a plurality of singulation lines 29.

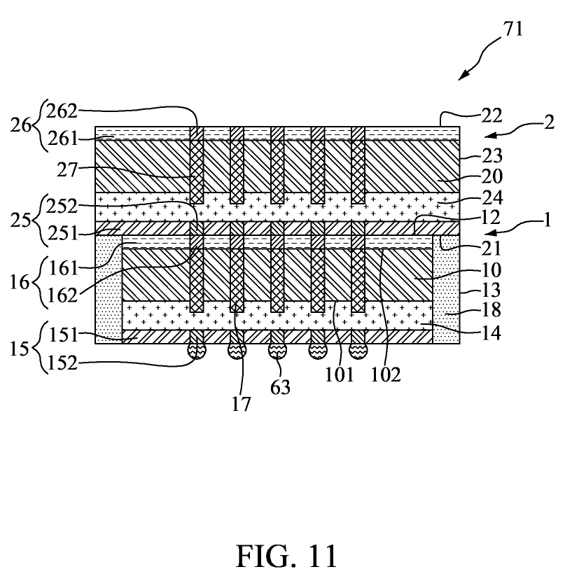

Referring to FIG. 11, the second wafer 2' and the first encapsulant 18 may be divided along the singulation lines 29 to form a plurality of first assemblies 71. The first assembly 71 may comprise a first semiconductor chip 1 and a second semiconductor chip 2 stacked on the first semiconductor chip 1 and electrically connected to the first semiconductor chip 1 by a hybrid bonding. The first semiconductor chip 1 may comprise the unit 1" and the first encapsulant 18. The second semiconductor chip 2 may be a portion divided from the second wafer 2'. The first assembly 71 of FIG. 11 may be same as or similar to the first assembly 71 of FIG. 1.

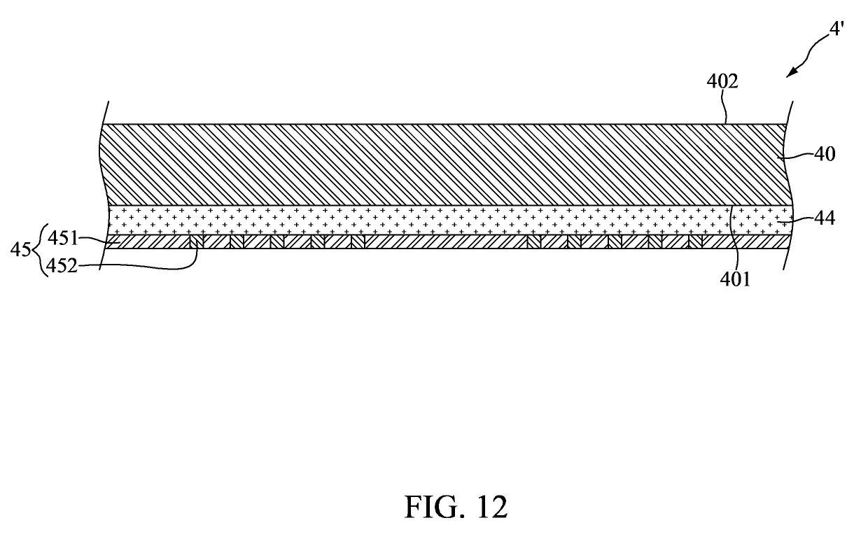

With reference to FIGS. 12 to 17, a second assembly 72 comprising a third semiconductor chip 3 and a fourth semiconductor chip 4 may be provided. The manufacturing of the second assembly 72 is described below.

Referring to FIG. 12, a fourth wafer 4' may be provided. The fourth wafer 4' may comprise a fourth base portion 40, a fourth conductive structure 44 and a fourth lower structure 45. The fourth base portion 40, the fourth conductive structure 44 and the fourth lower structure 45 of FIG. 12 may be same as or similar to the fourth base portion 40, the fourth conductive structure 44 and the fourth lower structure 45 of FIG. 1, respectively.

The fourth conductive structure 44 may be disposed on a first surface 401 (e.g., a bottom surface) of the fourth base portion 40. The fourth lower structure 45 may be disposed on the fourth conductive structure 44. The fourth lower structure 45 may comprise a fourth lower dielectric layer 451 and a plurality of fourth lower pads 452. The fourth lower pads 452 may be embedded in the fourth lower dielectric layer 451, and may be exposed by the fourth lower dielectric layer 451.

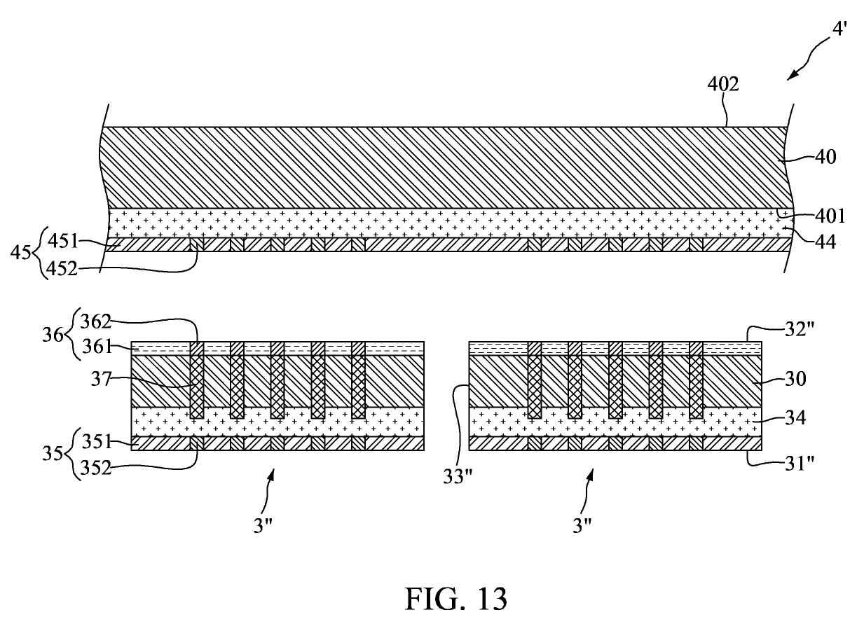

Referring to FIG. 13, a plurality of units 3" may be provided. The unit 3" may be same as or similar to the unit 1". The unit 3" may have a bottom surface 31" (e.g., a first surface) and a top surface 32" (e.g., a second surface), and may have a side surface 33" that extends between the bottom surface 31" and the top surface 32". The third semiconductor chip 3 may be same as or similar to the first semiconductor chip 1. The unit 3" may comprise a third base portion 30, a third conductive structure 34, a third lower structure 35, a third upper structure 36 and a plurality of third conductive vias 37 that are same as or similar to the third base portion 30, the third conductive structure 34, the third lower structure 35, the third upper structure 36 and the third conductive vias 37 of FIG. 1, respectively.

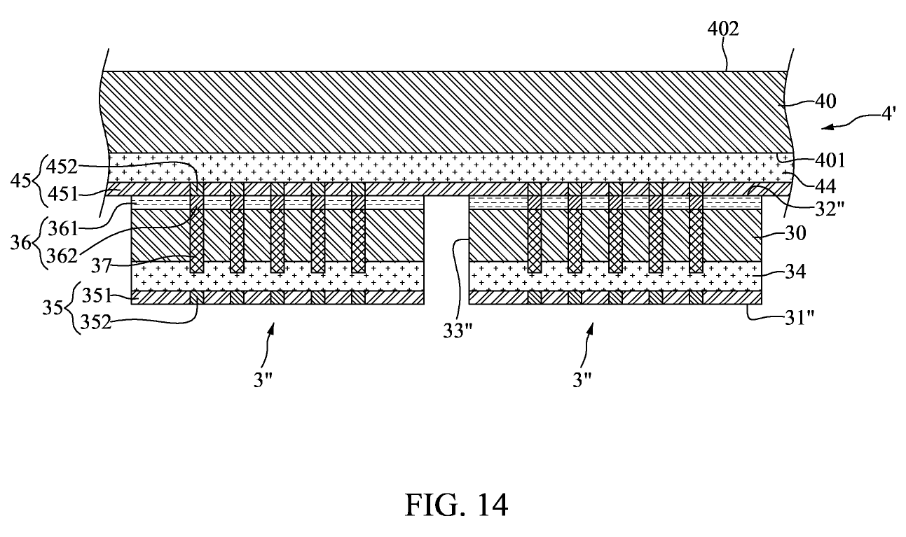

Referring to FIG. 14, the units 3" may be attached to the fourth wafer 4' through a hybrid bonding. The third upper dielectric layer 361 of the unit 3" may be attached to, bonded to or adhered to the fourth lower dielectric layer 451 of the fourth wafer 4' through a dielectric-to-dielectric bonding. The third upper pad 362 of the unit 3" may be attached to, joined to, or electrically connected to the fourth lower pad 452 of the fourth wafer 4' through a metal-to-metal bonding.

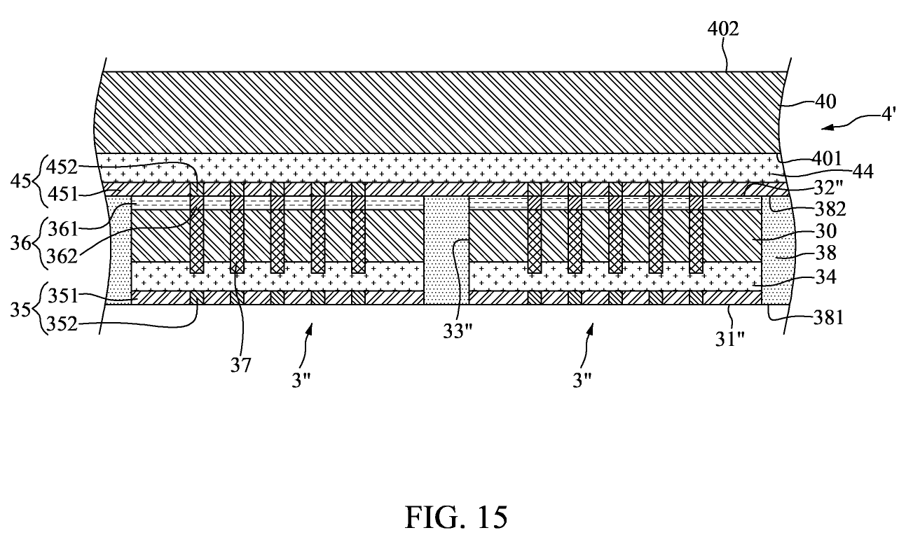

Referring to FIG. 15, a third encapsulant 38 may be formed or disposed on the fourth lower structure 45 to cover the units 3". The third encapsulant 38 may have a first surface 381 (e.g., a bottom surface) and a second surface 382 (e.g., a top surface) opposite to the first surface 381. The second surface 382 of the third encapsulant 38 may contact the fourth lower structure 45. The third encapsulant 38 may cover the side surface 33" and the bottom surface 31" of the unit 3".

In some embodiments, the third encapsulant 38 may be thinned from the first surface 381 (e.g., the bottom surface) to expose the units 3". In some embodiments, the first surface 381 of the third encapsulant 38 may be substantially coplanar with the bottom surfaces 31" of the units 3".

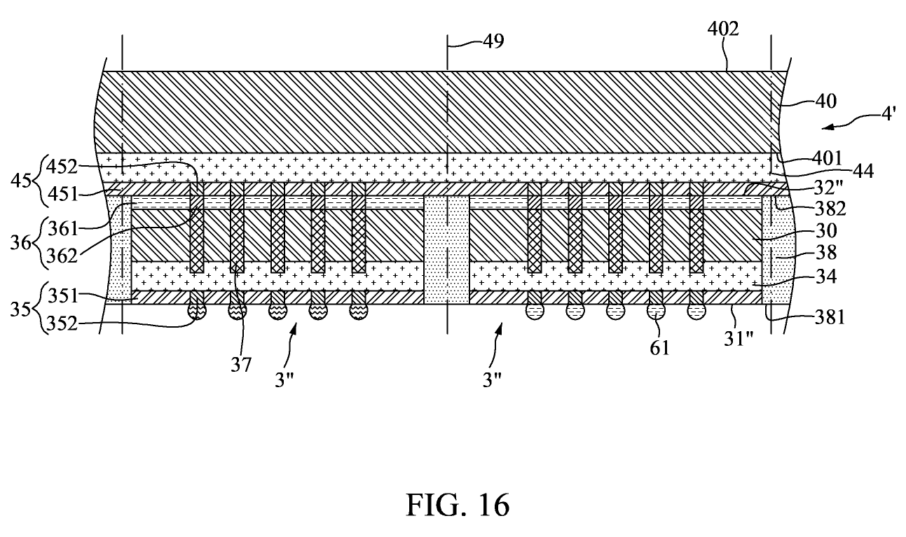

Referring to FIG. 16, a plurality of bumps 61 may be formed or disposed on the third lower pads 352 of the third lower structure 35 of the unit 3". The bumps 61 may include a reflowable material such as AgSn. Meanwhile, the fourth wafer 4' and the third encapsulant 38 may define a plurality of singulation lines 49.

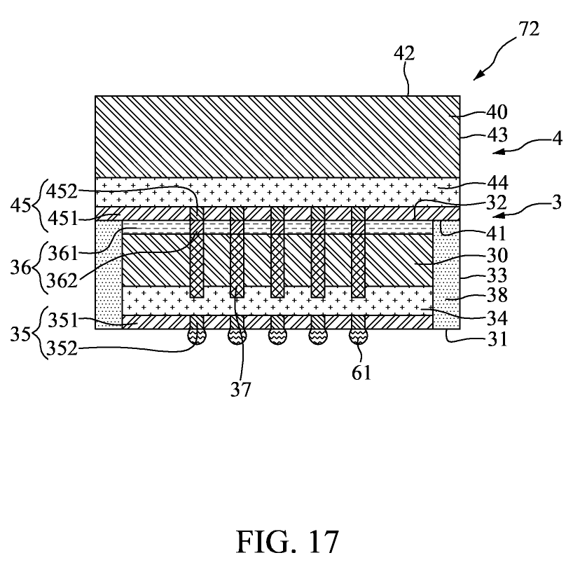

Referring to FIG. 17, the fourth wafer 4' and the third encapsulant 38 may be divided along the singulation lines 49 to form a plurality of second assemblies 72. The second assembly 72 may include a third semiconductor chip 3 and a fourth semiconductor chip 4 stacked on the third semiconductor chip 3 and electrically connected to the third semiconductor chip 3 by a hybrid bonding. The third semiconductor chip 3 may comprise the unit 3" and the third encapsulant 38. The fourth semiconductor chip 4 may be a portion divided from the fourth wafer 4'. The second assembly 72 of FIG. 17 may be same as or similar to the second assembly 72 of FIG. 1.

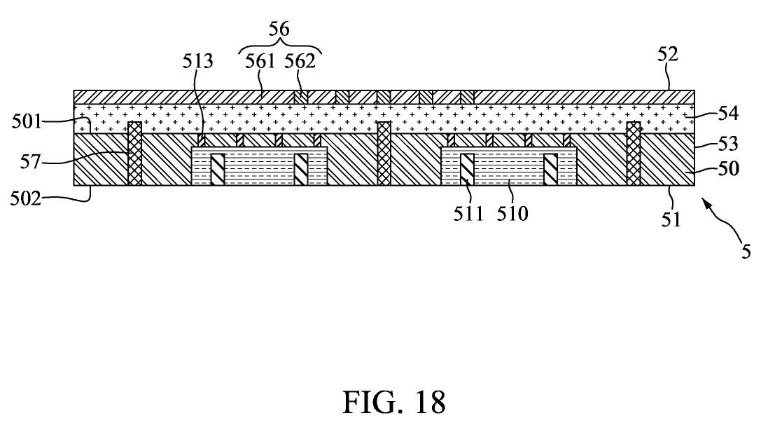

With reference to FIGS. 18 to 20, a third assembly 73 may be provided. The manufacturing of the third assembly 73 is described below.

Referring to FIG. 18, a fifth semiconductor chip 5 may be provided. The fifth semiconductor chip 5 may comprise a fifth base portion 50, a fifth conductive structure 54, a fifth upper structure 56, a plurality of fifth conductive vias 57 and a plurality of fifth dies 510. The fifth base portion 50, the fifth conductive structure 54, the fifth upper structure 56, the fifth conductive vias 57 and the fifth dies 510 of FIG. 18 may be same as or similar to the fifth base portion 50, the fifth conductive structure 54, the fifth upper structure 56, the fifth conductive vias 57 and the fifth dies 510 of FIG. 1, respectively. The fifth semiconductor chip 5 may have a bottom surface 51 (e.g., a first surface) and a top surface 52 (e.g., a second surface), and may have a side surface 53 that extends between the bottom surface 51 and the top surface 52.

It should be noted that the fifth semiconductor chip 5 may be a portion of a wafer in a manufacturing process. Once the manufacturing process is completed, the fifth semiconductor chip 5 may be divided from the wafer.

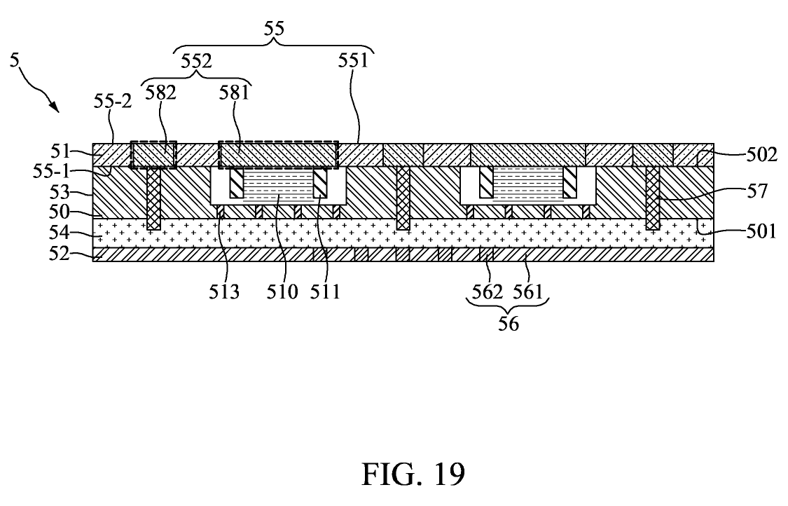

Referring to FIG. 19, a passivation layer 551 may be deposited on the bottom surface 51 (e.g., a first surface) of the fifth semiconductor chip 5, and may cover the fifth conductive vias 57, the fifth dies 510 and the fifth base portion 50. It should be noted that, prior to the deposition of the passivation layer 551 is performed, the fifth semiconductor chip 5’ may be flipped. Next, a conductive layer 552 may be formed penetrating through the passivation layer. In other words, the conductive layer 552 may be embedded in the passivation layer 551. The conductive layer 552 may comprise a plurality of portions 581, 582, wherein each portion 581/582 is separated and is electrically isolated from each other. In some embodiments, the portion 581 of the conductive layer 552 is electrically coupled to a plurality of conductive line 511 of the fifth die 510, and the portion 582 of the conductive layer 552 is electrically coupled to the fifth conductive via 57. In some embodiments, the portion 582 of the conductive layer 552 is isolated from the first portion 581 of the conductive layer 552. The passivation layer 551 may have a first surface 55-1 (e.g., a top surface) and a second surface 55-2 (e.g., a bottom surface) opposite to the first surface 55-1. In some embodiments, a top surface of the conductive layer 552 is coplanar with the first surface 55-1 (e.g., a top surface) of the passivation layer 551 and a bottom surface of the conductive layer 552 is coplanar with the second surface 55-2 (e.g., a bottom surface) of the passivation layer 551.

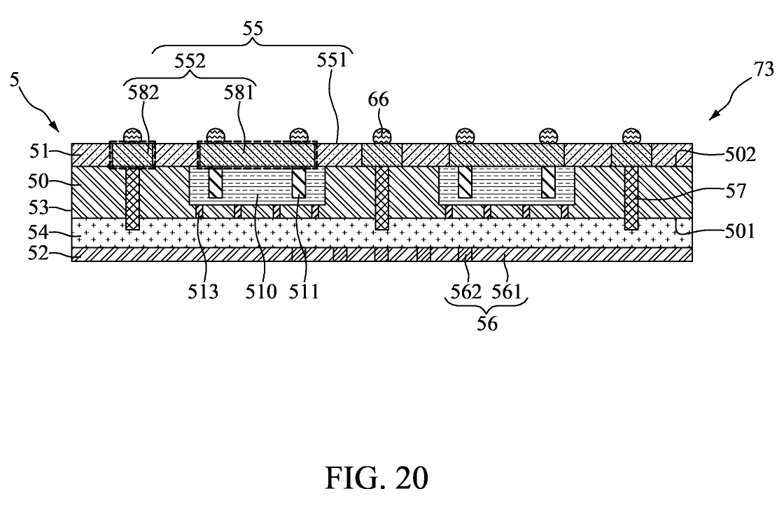

Referring to FIG. 20, a plurality of external connectors 66 may be disposed on the bottom surface of the conductive layer 552 for external connection. In some embodiments, the external connectors 66 may connect to the fifth conductive structure 54 through the second portions 582 of the conductive layer 552 and the fifth conductive vias 57. In some embodiments, the external connectors 66 may connect to the fifth dies 510 through the first portions 581 of the conductive layer 552 and the conductive lines 511. In some embodiments, the external connectors 66 may include a reflowable material such as AgSn. In some embodiments, the external connectors 66 may include solder balls, solder bumps or micro-bumps.

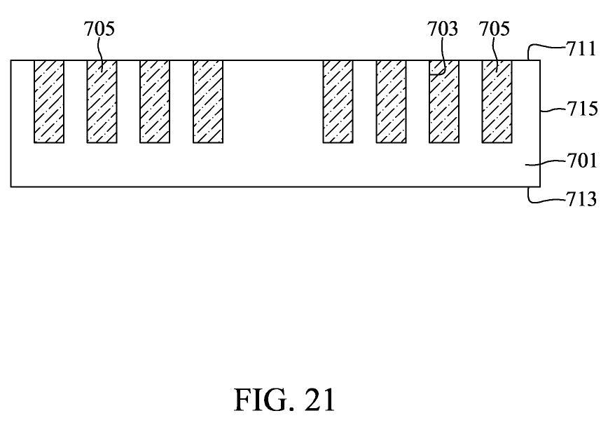

With reference to FIGS. 21 to 24, a carrier structure 700 comprising a heat dissipation unit HDU may be provided. Manufacturing of the carrier structure 700 is described below.

Referring to FIG. 21, a carrier substrate 701 with a plurality of via opening 703 may be provided. Next, a plurality of through semiconductor vias TSVs 705 may be formed to fill the via openings 503. The carrier substrate 701 and the TSV 705 of FIG. 20 may be same as or similar to the carrier substrate 701 and the TSV 705 of FIG. 1, respectively. The carrier substrate 701 may have a bottom surface 713 (e.g., a first surface) and a top surface 711 (e.g., a second surface), and may have a side surface 715 that extends between the bottom surface 51 and the top surface 52. In some embodiments, after the TSVs 705 are formed, a planarization process may be performed such that top surfaces of the TSVs 705 are substantially coplanar with the top surface 711 (e.g., the second surface) of the carrier substrate 701.

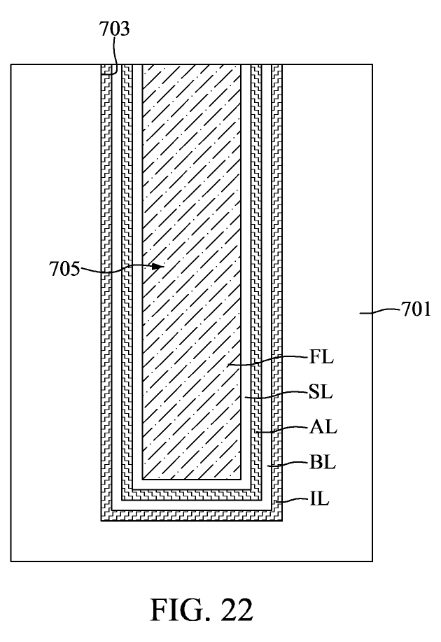

FIG. 22 is an enlarged view of the TSV 705 in FIG. 21. As shown in FIG. 22, the TSV 705 may include a filler layer FL, a seed layer SL, an adhesion layer AL, a barrier layer BL, and an isolation layer IL. The isolation layer IL may be conformally formed in the via opening 703 and may have a U-shaped cross-sectional profile. In some embodiments, the isolation layer IL may be formed of, for example, silicon oxide, silicon nitride, silicon oxynitride, or tetra-ethyl ortho-silicate. The isolation layer IL may have a thickness between about 50 nm and about 200 nm. Alternatively, in some embodiments, the isolation layer IL may be formed of, for example, parylene, epoxy, or poly(p-xylene). The isolation layer IL may have a thickness between about 1 μm and about 5 μm. The isolation layer IL may ensure the filler layer FL is electrically isolated in the carrier substrate 701.

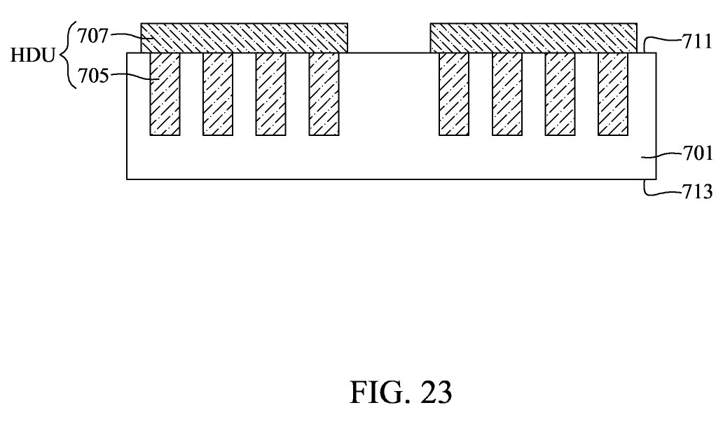

Referring to FIG. 23, a plurality of conductive plates 707 may be formed on the carrier substrate 501 and may be separated from each other. Each one of the conductive plates 707 may connect to two or more TSVs 705. The conductive plates 707 may be formed of, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. The conductive plates 707 and TSVs 705 together configure the heat dissipation unit HDU.

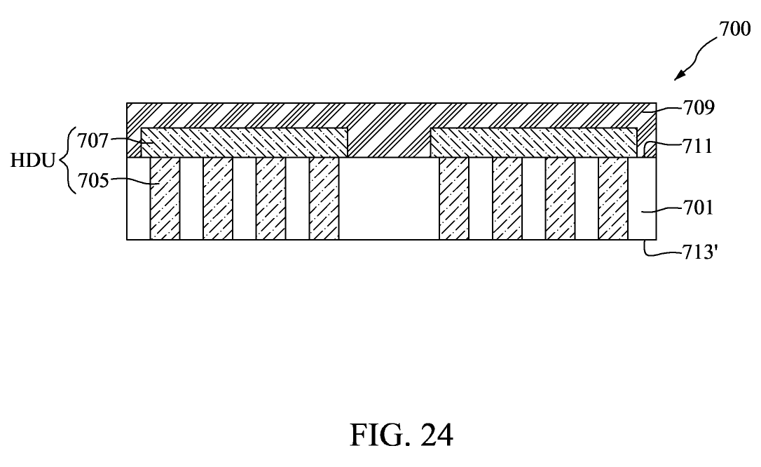

Referring to FIG. 24, a bonding layer 709 may be formed on the carrier substrate 701 and to cover the conductive plates 707. A planarization process, such as chemical mechanical polishing, may be performed to provide a substantially flat surface for subsequent processing steps. In some embodiments, the bonding layer 709 may be formed of, for example, a non-organic material selected from un-doped silicate glass, silicon nitride, silicon oxynitride, silicon oxide, silicon nitride oxide, and/or a combination thereof. In some embodiments, the bonding layer 709 may be formed of, for example, a polymer layer such as an epoxy, polyimide, benzocyclobutene, polybenzoxazole, or the like. The bonding layer 709 may be formed by a deposition process such as a chemical vapor deposition, a plasma-enhanced chemical vapor deposition, an evaporation, or a spin coating. The carrier substrate 701, the heat dissipation unit HDU, and the bonding layer 709 together configure the carrier structure 700. The carrier structure 700 may be employed to bond with another die (or another wafer) to form an intermediate stack structure for further bonding procedure.

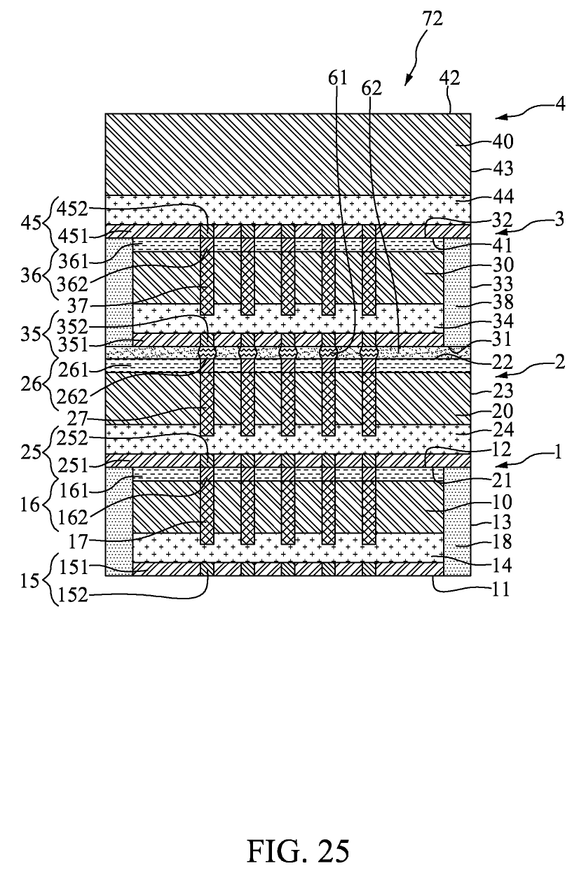

With reference to FIGS. 25 to 28, an electronic device 6 comprising a first assembly 71 (e.g., comprising a first semiconductor chip 1 and a second semiconductor chip 2), a second assembly 72 (e.g., comprising a third semiconductor chip 3 and a fourth semiconductor chip 4), a third assembly 73 (e.g., comprising a fifth semiconductor chip5 and a plurality of external connectors 66),a plurality of bumps 61, an underfill 62, a plurality of electrical connectors 63, a protection material 64, a periphery encapsulant 65, a carrier structure 700 and an intervening bonding layer 801 may be provided. Manufacturing of the electronic device 6 is described below.

Referring to FIG. 25, a second assembly 72 may be bonded to and electrically connected to a first assembly 71 through the bumps 61. In some embodiments, an underfill 62 may be formed or disposed in a space between the second assembly 72 and the first assembly 71 to cover the bumps 61.

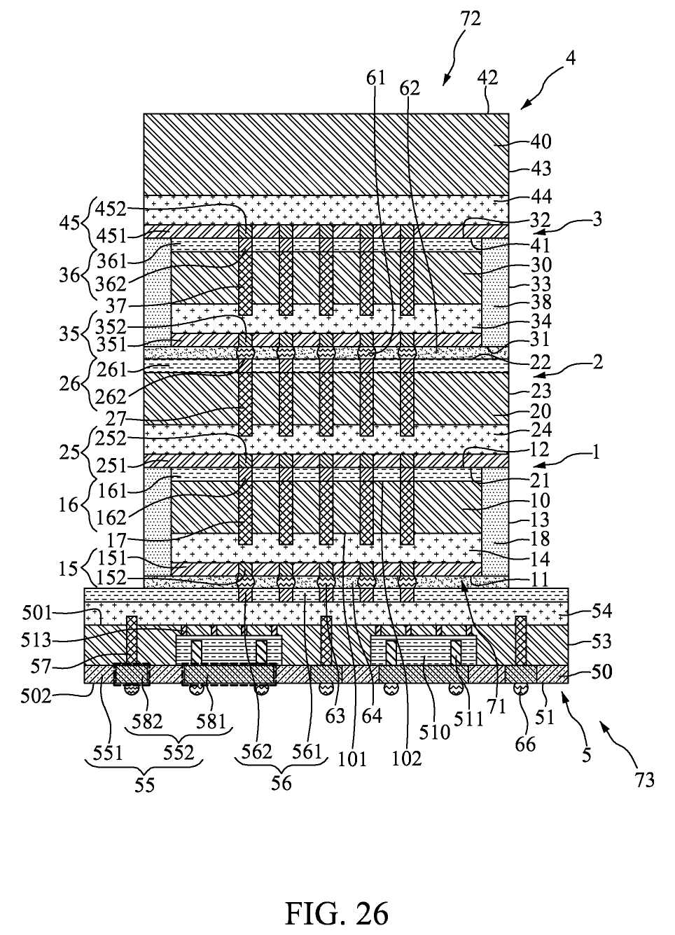

Referring to FIG. 26, the first assembly 71 and the second assembly 72 may be bonded to and electrically connected to a third assembly 73 through the electrical connectors 63. In some embodiments, a protection material 64 may be formed or disposed between the first assembly 71 (or the first semiconductor chip 1) and the third assembly 73 (or the fifth semiconductor chip 5) to cover the electrical connectors 63.

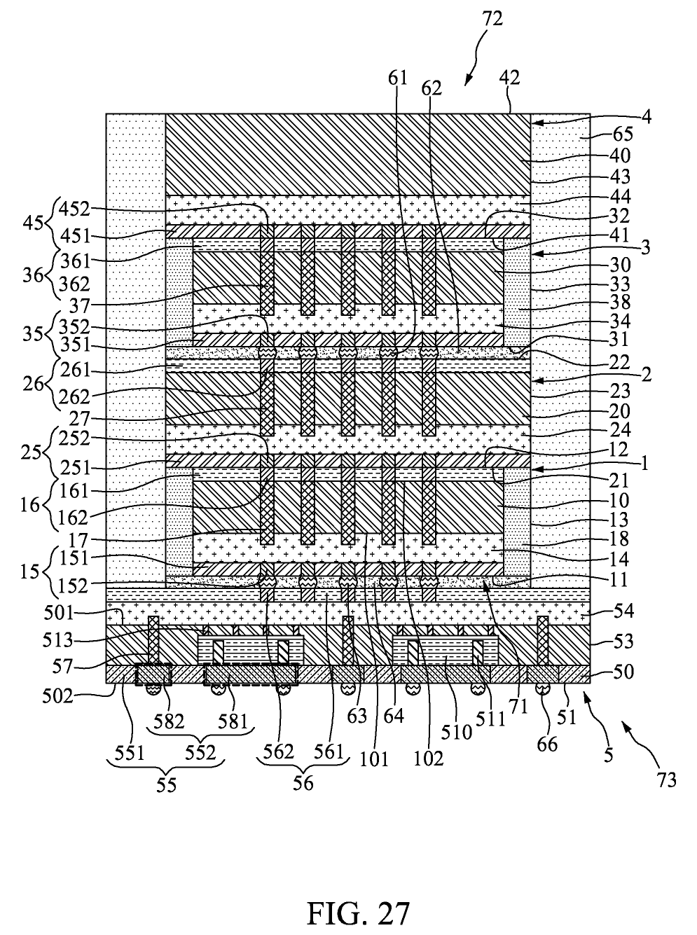

Referring to FIG. 27, a periphery encapsulant 65 may be formed to encapsulate the first assembly 71 (comprising the first semiconductor chip 1 and the second semiconductor chip 2), the second assembly 72 (comprising the third semiconductor chip 3 and the fourth semiconductor chip 4) and third assembly 73 (comprising the fifth semiconductor chip 5 and the plurality of external connectors 66).

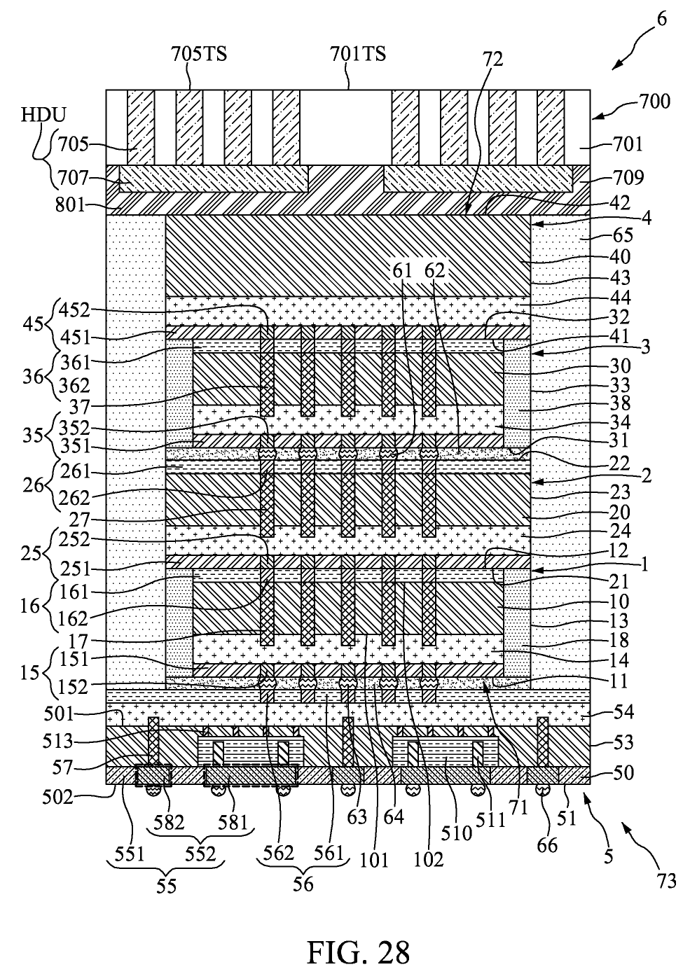

Referring to FIG. 28, a carrier structure 700 may be bonded to the second assembly 72 through an intervening bonding layer 801. It should be noted that, prior to the bonding of the carrier structure 700 to the second assembly 72, the carrier structure 700 may be flipped. After the carrier structure 700 is bonded to the second assembly 72, the electronic device 6 can be obtained.

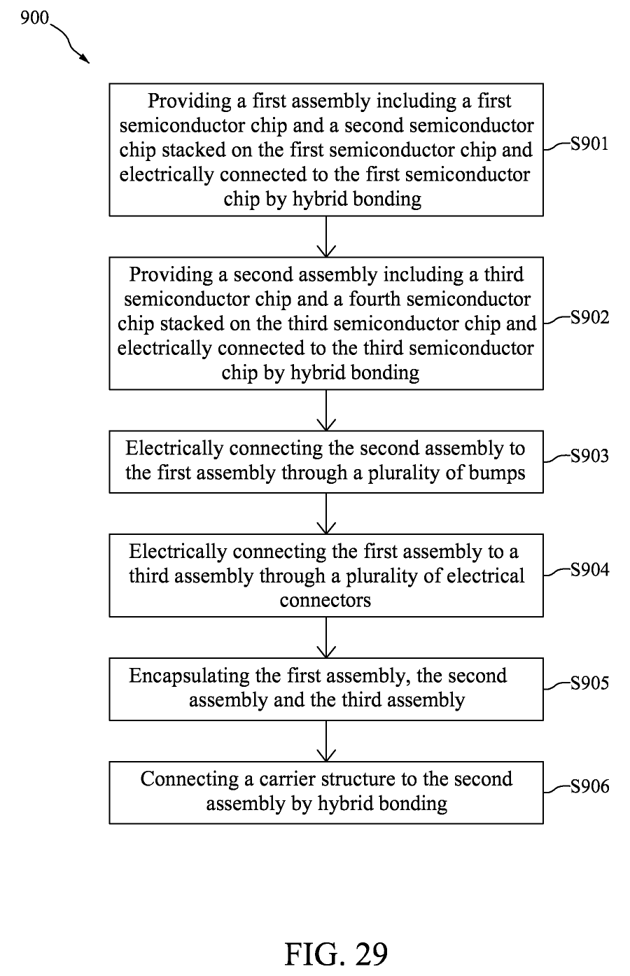

FIG. 29 is a flow diagram of a method 900 of manufacturing an electronic device 6 in accordance with some embodiments of the present disclosure.

In some embodiments, the method 900 may include a step S901, providing a first assembly comprising a first semiconductor chip and a second semiconductor chip stacked on the first semiconductor chip and electrically connected to the first semiconductor chip by hybrid bonding. For example, as shown in FIG. 11, a first assembly 71 may be provided. The first assembly 71 comprises a first semiconductor chip 1 and a second semiconductor chip 2 stacked on the first semiconductor chip 1 and electrically connected to the first semiconductor chip 1 by hybrid bonding.

In some embodiments, the method 900 may include a step S902, providing a second assembly comprising a third semiconductor chip and a fourth semiconductor chip stacked on the third semiconductor chip and electrically connected to the third semiconductor chip by hybrid bonding. For example, as shown in FIG. 17, a second assembly 72 may be provided. The second assembly 72 comprises a third semiconductor chip 3 and a fourth semiconductor chip 4 stacked on the third semiconductor chip 3 and electrically connected to the third semiconductor chip 3 by hybrid bonding.

In some embodiments, the method 900 may include a step S903, electrically connecting the second assembly to the first assembly through a plurality of bumps. For example, as shown in FIG. 25, the second assembly 72 may be electrically connected to the first assembly 71 through a plurality of bumps 61.

In some embodiments, the method 900 may include a step S904, electrically connecting the first assembly to a third assembly 73 comprising a fifth semiconductor chip and a plurality of external connectors 66 through a plurality of electrical connectors. For example, as shown in FIG. 26, the second assembly 71 may be electrically connected to the third assembly 73 through a plurality of electrical connectors 63.

In some embodiments, the method 900 may include a step S905, encapsulating the first assembly, the second assembly and the third assembly. For example, as shown in FIG. 27, the periphery encapsulant 65 may encapsulate the first assembly 71, the second assembly 72 and the third assembly 73.

In some embodiments, the method 900 may include a step S906, connecting a carrier structure to the second assembly by hybrid bonding. For example, as shown in FIG. 28, the carrier structure 700 is connected to the second assembly 72 by hybrid bonding. It should be noted that, prior to the bonding of the carrier structure 700 to the second assembly 72, the carrier structure 700 is flipped.

One aspect of the present disclosure provides an electronic device comprising a first semiconductor chip; a second semiconductor chip stacked on the first semiconductor chip, and electrically connected to the first semiconductor chip by hybrid bonding; a third semiconductor chip stacked on the second semiconductor chip, and electrically connected to the second semiconductor chip through a plurality of bumps; a fourth semiconductor chip stacked on the third semiconductor chip, and electrically connected to the third semiconductor chip by hybrid bonding; and a fifth semiconductor chip disposed below the first semiconductor chip, and electrically connected to the first semiconductor chip through a plurality of electrical connectors.

Another aspect of the present disclosure provides an electronic device comprising a first assembly, a second assembly, a base semiconductor chip and a carrier structure. The first assembly comprises a first semiconductor chip and a second semiconductor chip stacked on the first semiconductor chip, and the second semiconductor chip is electrically connected to the first semiconductor chip by hybrid bonding. The second assembly comprises a third semiconductor chip and a fourth semiconductor chip stacked on the third semiconductor chip, and the fourth semiconductor chip is electrically connected to the third semiconductor chip by hybrid bonding. The base semiconductor chip is disposed below the first assembly and electrically connected to the first assembly through a plurality of electrical connectors. The carrier structure is disposed over the second assembly and electrically connected to the second assembly through by a hybrid bonding. The second assembly is electrically connected to the first assembly through a plurality of bumps. The first assembly is electrically connected to the base semiconductor chip through a plurality of electrical connectors.

Another aspect of the present disclosure provides a manufacturing method. The manufacturing method comprises forming a first assembly comprising a first semiconductor chip, a second semiconductor chip and a plurality of electrical connectors, wherein the second semiconductor chip is stacked on the first semiconductor chip, and wherein the electrical connectors are connected to the first semiconductor chip; forming a second assembly comprising a third semiconductor chip, a fourth semiconductor chip and a plurality of bumps, wherein the fourth semiconductor chip is stacked on the third semiconductor chip, and wherein the bumps are connected to the third semiconductor chip; forming a third assembly comprising a fifth semiconductor chip and a plurality of external connectors, wherein the third assembly comprises a fifth lower structure and a fifth upper structure, and wherein the external connectors are connected to the fifth lower structure; forming a carrier structure comprising a carrier substrate, a plurality of through semiconductor vias penetrating the carrier substrate, a plurality of conductive plates on the carrier substrate and the through semiconductor vias, and a bonding layer on the carrier substrate and covering the conductive plates; electrically connecting the second assembly to the first assembly through the plurality of bumps; electrically connecting the first assembly to the third assembly through the plurality of electrical connectors; encapsulating the first assembly, the second assembly and the third assembly with a periphery encapsulant around the first assembly and the second assembly, and on the third assembly; and performing a hybrid bonding to electrically connect the carrier structure to the second assembly and the periphery encapsulant.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

WHAT IS CLAIMED IS:

1. A method of preparing an electronic device, comprising:
forming a first assembly comprising a first semiconductor chip, a second semiconductor chip and a plurality of electrical connectors, wherein the second semiconductor chip is stacked on the first semiconductor chip, and wherein the electrical connectors are connected to the first semiconductor chip;
forming a second assembly comprising a third semiconductor chip, a fourth semiconductor chip and a plurality of bumps, wherein the fourth semiconductor chip is stacked on the third semiconductor chip, and wherein the bumps are connected to the third semiconductor chip;
forming a third assembly comprising a fifth semiconductor chip and a plurality of external connectors, wherein the third assembly comprises a fifth lower structure and a fifth upper structure, and wherein the external connectors are connected to the fifth lower structure;
forming a carrier structure comprising a carrier substrate, a plurality of through semiconductor vias penetrating the carrier substrate, a plurality of conductive plates on the carrier substrate and the through semiconductor vias, and a bonding layer on the carrier substrate and covering the conductive plates;
electrically connecting the second assembly to the first assembly through the plurality of bumps;
electrically connecting the first assembly to the third assembly through the plurality of electrical connectors;
encapsulating the first assembly, the second assembly and the third assembly with a periphery encapsulant around the first assembly and the second assembly, and on the third assembly; and
performing a hybrid bonding to electrically connect the carrier structure to the second assembly and the periphery encapsulant.

2. The method of claim 1, wherein the formation of the first assembly comprises:
providing a first wafer;
forming a plurality of first unit divided from the first wafer;
providing a second wafer;
connecting the first units to the second wafer;
encapsulating the first units with a first encapsulant around the first units;
thinning the second wafer, and forming an upper structure on the second wafer;
thinning the first encapsulant, and forming a plurality of electrical connectors on a low structure of the first units; and
dividing the first encapsulant and the second wafer through singulation lines, such that the first assembly comprises a first semiconductor chip, a second semiconductor chip and a plurality of electrical connectors are formed.

3. The method of claim 1, wherein the formation of the second assembly comprises:
providing a fourth wafer;
providing a plurality of third unit;
connecting the third units to the fourth wafer;
encapsulating the third units with a third encapsulant around the third units;
forming a plurality of bumps on a third lower structure of the third units; and
dividing the fourth wafer and the plurality of third units through singulation lines, such that the second assembly comprises a third semiconductor chip and a fourth semiconductor chip are formed.

4. The method of claim 1, wherein the formation of the third assembly comprises:
providing a semiconductor chip comprising a base portion, a conductive structure disposed on a top surface of the base portion, a plurality of conductive vias extending through the base portion and electrically connected to the conductive structure, a plurality of fifth dies disposed in a bottom surface of the base portion, a plurality of contact pads formed on the fifth die and an upper structure disposed on the conductive structure;
performing a flip operation to flip the semiconductor chip, and forming a lower structure of the fifth semiconductor chip on the bottom surface of the base portion, wherein the formation of the lower structure comprises:
depositing a passivation layer on the bottom surface of the base portion to cover the fifth die, the conductive vias and the base portion; and
forming a conductive layer fifth dies penetrating through the passivation layer, wherein the conductive layer comprises a first portion electrically coupled to the fifth dies through a plurality of conductive lines and a second portion electrically isolated from the first portion and contacting the conductive vias; and
forming a plurality of external connectors connected to the conductive layer.

5. The method of claim 1, wherein the formation of the carrier structure comprises:
providing a carrier substrate with a plurality of via opening, and forming a plurality of through semiconductor vias in the openings;
forming a plurality of conductive plates on the carrier substrate and the through semiconductor vias; and
forming a bonding layer on the carrier substrate and covering the conductive plates.

6. The method of claim 1, further comprising forming an underfill between the second assembly and the first assembly and covering the bumps.

7. The method of claim 1, further comprising forming a protection material between the first assembly and the third assembly and covering the electrical connectors.

8. The method of claim 1, wherein the performing of the hybrid bonding comprises:
forming an intervening bonding layer on the second assembly and the periphery encapsulant;
performing a flip operation to flip the carrier structure; and
stacking the carrier structure over the intervening bonding layer.
